(19) United States
(12) Patent Application Publication
(10) Pub. No.: US 2016/0318190 A1
(43) Pub. Date: Nov. 3, 2016

(54) MODULAR ELECTROADHESIVE GRIPPING SYSTEM

(71) Applicant: GRABIT, INC., Santa Clara, CA (US)

(72) Inventors: Harsha PRAHLAD, Cupertino, CA (US); Eric Robert WINGER, Ben Lomond, CA (US); Bobby Neil ROY, Fremont, CA (US); Susan KIM, Menlo Park, CA (US); Patrick BOURNES, Santa Clara, CA (US)

(21) Appl. No.: 15/105,941

(22) PCT Filed: Dec. 19, 2014
(86) PCT No.: PCT/US2014/071725

§ 371 Date: Jun. 17, 2016

Related U.S. Application Data
(60) Provisional application No. 61/919,602, filed on Dec. 20, 2013.

(51) Int. Cl. B25J 15/00; H02N 13/00; H01L 21/683

(52) U.S. Cl. CPC B25J 15/0085; H01L 21/6833; H02N 13/00

(57) ABSTRACT

Automated manufacturing often requires reliable tools for acquiring or moving items in a manufacturing process. An electroadhesive gripper utilizes electroadhesive surfaces to acquire and move items from one step in a process to another. An electroadhesive surface can include electrodes that are configured to induce an electrostatic attraction with nearby objects upon application of voltage to the electrodes. Systems described herein also employ a load-bearing frame that is coupled to an electroadhesive gripping surface. Components of these electroadhesive systems may be configured to be modular in construction to simplify construction and maintenance. Some components may be disposable or require more frequent repair than other components. Modular assembly and component construction simplifies maintenance and reduces overall costs of operation.

### CROSS-REFERENCE AND RELATED APPLICATIONS

This application claims the benefit of U.S. Provisional Application 61/919,602, filed Dec. 20, 2013, which application is incorporated by reference.

### TECHNICAL FIELD

The present invention relates to automated manufacturing. More particularly, the present invention relates to, in an automated manner, picking up substrates or sub-assembly components, for example, parts that form all or part of an assembly, and providing a modular system for acquiring or moving said items in a manufacturing process.

### BACKGROUND OF THE INVENTION

Unless otherwise indicated herein, the materials described in this section are not prior art to the claims in this application and are not admitted to be prior art by inclusion in this section.

The mass production of products has led to many innovations over the years. Substantial developments have been made in the industrial handling of various materials and items, particularly in the area of robotics. For example, various types of robotics and other automated systems are now used in order to “pick and place” items during many manufacturing and other materials handling processes. Such robotics and other systems can include robot arms that, for example, grip, lift and/or place an item as part of a designated process. Of course, other manipulations and materials handling techniques can also be accomplished by way of such robotics or other automated systems. Despite many advances over the years in this field, there are limitations as to what can be handled in such a manner.

Conventional robotic grippers typically use either suction or a combination of large normal forces and fine control with mechanical actuation in order to grip objects. Such techniques have several drawbacks. For example, the use of suction tends to require smooth, clean, dry and generally flat surfaces, which limits the types and conditions of objects that can be gripped. Suction also tends to require a lot of power for the pumps and is prone to leaks at any location on a vacuum or low pressure seal, with a resulting loss of suction being potentially catastrophic. The use of mechanical actuation often requires large normal or “crushing” forces against an object, and also tends to limit the ability to robotically grip fragile or delicate objects. Producing large forces also increases the cost of mechanical actuation. Mechanical pumps and conventional mechanical actuation with large crushing forces also often require substantial weight, which is a major disadvantage for some applications, such as the end of a robot arm where added mass must be supported. Furthermore, even when used with sturdy objects, robotic arms, mechanical claws and the like can still leave damaging marks on the surface of the object itself.

Alternative techniques for handling items and materials also have drawbacks. For example, chemical adhesives can leave residues and tend to attract dust and other debris that reduce effectiveness. Chemical adhesives can also require a significant amount of added force to undo or overcome a grip or attachment to an object once such a chemical adhesive grip or attachment is applied, since the gripping interaction and force is typically not reversible in such instances.

### SUMMARY OF THE INVENTION

Although many systems and techniques for handling materials in an automated fashion have generally worked well in the past, there is always a desired to provide alternative and improved ways of handling items. In particular, what is desirable are new automated systems and techniques that permit the picking and placing or other handling of objects that are large, irregular shaped, dusty and/or fragile, and preferably with little to no use of suction, chemical adhesives or significant mechanical normal forces against the objects.

Provided herein is an electroadhesive gripping system used in manufacturing for acquiring or moving items a manufacturing process, having a frame, a cartridge, an electroadhesive film with one or more electrodes at or near the electroadhesive gripping surface, and a power supply, wherein the system may be constructed in a modular fashion to simplify construction and maintenance. Some components may be disposable or require more frequent repair than other components. Modular assembly and modular component construction simplifies and expedites maintenance, and reduces overall costs of operation.

Provided herein is an electroadhesive gripping system comprising: a frame having a superior surface and an inferior surface; a cartridge having a superior and inferior surface wherein the superior surface is detachably connectable to the inferior surface of said frame; an electroadhesive film with one or more electrodes at or near the gripping surface, and a backing surface of said electroadhesive film at least partially covering and connectable to the inferior surface of said cartridge, or optionally extending over a portion of the superior surface of said frame; and a power supply coupled to the superior surface of said frame, configured to apply voltage to the one or more electrodes of the electroadhesive film, wherein at least a portion of said connecting interface of said electroadhesive film is in direct contact with said power supply.

In some embodiments of the electroadhesive gripping system, the frame further comprises side walls comprising interior and exterior faces, creating a cavity within the frame between the inferior surface and the interior faces of said sides.

In some embodiments of the electroadhesive gripping system, the cartridge fits, at least partially, within, and conforms to the cavity of the frame.

In some embodiments, the electroadhesive gripping system further comprises a deformable or conformable layer dispersed between the inferior surface of the cartridge and the backing surface of the electroadhesive film.

In some embodiments, the electroadhesive gripping system, the frame is load-bearing. In other embodiments, the frame is metallic. In still other embodiments the frame may be magnetic. In yet other embodiments, the frame may be non-metallic or electrically non-conductive.

In some embodiments of the electroadhesive gripping system, the electroadhesive film comprising one or more electrodes at or near the surface and having a connecting interface also comprises at least one contact pad that connect to the one or more electrodes. The contact pad may be patterned on the film as a separate area, or may include separate mechanical or electrical features attached to the film, these features comprising: a conductive area or pattern; a pogo pin; a leaf spring; a carbon brush; a spring contact; a metallic contact button; a wiring connector; a wiring harness; a rare earth magnet; a ferrite magnet; an alnico magnet; or a ferromagnetic contact.

In some embodiments of the electroadhesive gripping system, the power supply also comprises at least one contact point for connecting and transferring power to the at least one contact pad of the connecting interface of the electroadhesive film and transferring voltage to the electrodes. The contact point may comprise: a pogo pin; a leaf spring; a carbon brush; a spring contact; a metallic contact button; a wiring connector; a wiring harness; a rare earth magnet; a ferrite magnet; an alnico magnet; or a ferromagnetic contact.

In still other embodiments, the contact point(s) and/or contact pad(s) comprise electrical insulators. In other embodiments, the entire connecting interface of the electroadhesive film may be insulated from the frame.

In any one of the embodiments of the electroadhesive gripping system described herein, the power supply is separable from the frame.

Still further, any of the embodiments of the electroadhesive gripping system described herein comprise at least one attachment mechanism to retain the adjoining surfaces of the various components, at least partially, within intimate contact with each other. The various adjoining surfaces may include: the power supply and the frame; the power supply and the electroadhesive film connecting interface; the frame and the cartridge; the cartridge and the deformable layer; the cartridge and the electroadhesive film; the deformable layer and the electroadhesive film; the electroadhesive film and the frame; or the connecting interface and the frame.

In any one of the embodiments or adjoining surfaces described herein, the attachment mechanism may include: a chemical adhesive; a mechanical fastener, a heat fastener (e.g.: welded, spot welded, or spot-melted location); dry adhesion; Velcro; suction/vacuum adhesion; magnetic attachment, electromagnetic attachment or tape (e.g.: single- or double-sided). Depending on the degree of modularity desired or needed for a given situation, the attachment mechanism may create a permanent, temporary or even a removable form of attachment.

Provided herein is an electroadhesive gripping system comprising: a frame having a superior surface and an inferior surface; a cartridge having a superior surface and inferior surface, detachably connectable to the inferior surface of the frame; an electroadhesive film with one or more electrodes at or near the gripping surface, and a backing surface of said electroadhesive film at least partially covering and detachably connected to the inferior surface of said cartridge, and comprising a first connecting interface; and a power supply comprising a second connecting interface configured to apply voltage to the one or more electrodes of the electroadhesive film through the second connecting interface.

In some embodiments of the electroadhesive gripping system, the frame further comprises side walls comprising interior and exterior faces, creating a cavity within the frame between the inferior surface and the interior faces of said sides.

In some embodiments of the electroadhesive gripping system, the cartridge fits, at least partially, within, and conforms to the cavity of the frame.

In some embodiments, the electroadhesive gripping system, the frame is load-bearing. In other embodiments, the frame is metallic. In still other embodiments the frame may be magnetic. In yet other embodiments, the frame may be non-metallic or electrically non-conductive.

In some embodiments, the electroadhesive gripping system further comprises a deformable or conformable layer dispersed between the superior surface of the cartridge and the backing surface of said electroadhesive film.

In some embodiments of the electroadhesive gripping system, the cartridge and said electroadhesive film combine as a separable cartridge sub-assembly. In other embodiments, the cartridge, said deformable or conformable layer, and said electroadhesive film combine as yet another type of separable cartridge sub-assembly.

In some embodiments of the electroadhesive gripping system, the power supply is separable from the frame. In still other embodiments, the power supply is completely remote and detached from the frame: For example, wherein the power supply is located on the robotic arm or base of the robotic arm holding the electroadhesive gripping system and power is applied from the power supply to the electroadhesive gripper via wired connections or through a wiring harness.

In any one of the embodiments of the electroadhesive gripping system described herein, the first or second connecting interface of the system is electrically insulated from said frame when assembled. In still other embodiments, the entire connecting interface of the electroadhesive film may be insulated.

In various embodiments, the first or second connecting interface may comprise at least one of: a wire; a connector; a pogo pin; a leaf spring; a carbon brush; a spring contact; a metallic contact button; a wiring connector, a wiring harness; a rare earth magnet; a ferrite magnet; an alnico magnet; or a ferromagnetic contact.

In any one of the embodiments of the electroadhesive gripping system described herein, the power supply is separable from the frame.

Still further, any of the embodiments of the electroadhesive gripping system described herein comprise at least one attachment mechanism to retain the adjoining surfaces of the various components, at least partially, within intimate contact with each other. The various adjoining surfaces may include: the power supply and the frame; the cartridge and the deformable layer, the deformable layer and the electroadhesive film, or the cartridge and the electroadhesive film.

In any one of the embodiments or adjoining surfaces described herein, the attachment mechanism may include: a chemical adhesive; a mechanical fastener, a heat fastener (e.g.: welded, spot welded, or spot-melted location); dry adhesion; Velcro; suction/vacuum adhesion; magnetic or electromagnetic attachment or tape (e.g.: single- or double-sided). Depending on the degree of modularity desired or needed for a given situation, the attachment mechanism may create a permanent, temporary or even removable form of attachment.

Provided herein is an electroadhesive gripping system comprising an electroadhesive gripping system comprising: a frame having a superior surface and an inferior surface; a cartridge having a superior surface and inferior surface detachably connectable to said inferior surface of said frame; an electroadhesive film with one or more electrodes at or near a gripping surface, a backing surface at least partially covering and detachably connectable to the inferior surface of said cartridge and comprising a first connecting interface; a power supply comprising a second connecting interface configured to apply voltage to the one or more electrodes of the electroadhesive film through said second connecting interface.

Provided herein is an electroadhesive gripping system comprising any of the configurations described herein, and further comprising at least one detachable interface.

In some embodiments the detachable interface is between the power supply and frame. In other embodiments the detachable interface is between the frame and the cartridge, or the frame and the cartridge assembly.

In some embodiments of the electroadhesive gripping system, the at least one detachable interface utilizes an attachment mechanism comprising at least one of: a chemical adhesive; a mechanical fastener; Velcro; tape; a magnet; or an electroadhesive surface. In some cases, when magnetic means are utilized, the magnets may comprise: a rare earth magnet; a ferrite magnet; an alnico magnet; an electromagnets; or a ferromagnetic contact. The attachment mechanism may pertain to the method of attaching the detachable interface to the gripping system components, or in some cases the attachment mechanism may pertain to the method of attaching the detachable interfaces themselves together.

In yet other embodiments of the electroadhesive gripping system, the at least one detachable interface further comprises a magnetic shim plate. Still further the magnetic shim plate is coupled to the superior surface of the cartridge. In other embodiments the magnetic shim plate is coupled to the inferior surface of the frame. As with other component interfaces already described, an attachment mechanism such as: a chemical adhesive; a mechanical fastener, a dry adhesion surface; vacuum or suction; Velcro; tape; or a magnet may be utilized to adhere or couple the shim plate to the mating component surface. Again, depending on the degree of modularity desired or needed for a given situation, the attachment mechanism may create a permanent, temporary or even a removable form of attachment.

In some embodiments the shim plate may not be magnetic. In some embodiments the shim plate may be a metal plate; a non-metallic plate; or a non-magnetic plate.

Still further, in other embodiments of the electroadhesive gripping system comprising a detachable interface with a shim plate, yet another detachable attachment mechanism is utilized between said shim plate and the opposing coupling surface on the other side of the detachable interface. For example, the additional attachment mechanism may comprise: a (temporary) chemical adhesive; a mechanical fastener; a magnet; dry adhesion; Velcro; suction/vacuum adhesion; or tape. Where magnetic means are utilized, the magnets may comprise: a rare earth magnet; a ferrite magnet; an alnico magnet; an electromagnets; or a ferromagnetic contact.

In still other embodiments, the detachable interface may comprise two shim plates: wherein at least one side of the detachable interface comprises (at least one) first shim plate coupled to the inferior surface of the frame and (at least one) second shim plate coupled to the superior surface of the cartridge or cartridge assembly.

Still further, the at least one detachable interface comprising said first and second shim plate could comprise at least one of: a metal plate; a magnetic plate; a non-metallic plate; or a non-magnetic plate.

In any of the preceding shim plate embodiments having a detachable interface, there may exist another attachment mechanism between the shim plates themselves comprising at least one of: magnets; electrostatic adhesion; Van-der-Waals forces; dry adhesion; vacuum/suction; a temporary adhesive; a meltable adhesive; and a mechanical fastener.

In some embodiments, one skilled in the art would recognize that the power supply mechanism of any one of the configurations described and configured for activating the electroadhesive film, may be the same or different from a power supply mechanism configured for activating the electrostatic adhesion forces for the detachable interface comprising said first and second shim plates.

As previously suggested, the power supply of any of the systems having a detachable interface may have a power supply that is separable from the frame. The means or method of separation of the power supply may or may not be the same as the detachable interface.

In any of the aforementioned embodiments, the electroadhesive gripping system may include a conformable/deformable layer between the cartridge and electroadhesive film. Said conformable/deformable layer may comprise: foam, a polymer, an elastomeric material, or a bladder. Still further the bladder may be a hydraulic or pneumatic bladder. Still further, the bladder may be filled with a compressible or loosely packed material, such as polymer beads, sand, Styrofoam, beans, husks or other similar material, that would provide compliance to the electroadhesive gripper film surface, allowing for better conformance to a non-smooth or non-flat foreign surface.

Provided herein is an electroadhesive gripping system comprising a frame having a superior surface and an inferior surface; a cartridge having a superior surface and inferior surface, wherein said superior surface is detachably connectable to said inferior surface of said frame; an electroadhesive film with one or more electrodes at or near a gripping surface, a backing surface at least partially covering and connectable to the inferior surface of said cartridge and comprising a voltage connector interface; and a power supply configured to apply voltage to the one or more electrodes of the electroadhesive film.

In some embodiments, the electroadhesive film is configured to at least partially cover the inferior surface of said cartridge wherein the coverage is defined as a range of areas of any one or more of the following from 10% to 100%; from 20% to 100%; from 30% to 100%; from 40% to 100%; from 50% to 100%; from 60% to 100%; from 70% to 100%; from 80% to 100%; from 90% to 100%; and from 95% to 100%.

In some embodiments, the electroadhesive film is configured to at least partially cover the inferior surface of said cartridge wherein the coverage is defined as a range of areas of any one or more of the following from about 10% to about 100%; from about 20% to about 100%; from about 30% to about 100%; from about 40% to about 100%; from about 50% to about 100%; from about 60% to about 100%; from about 70% to about 100%; from about 80% to about 100%; from about 90% to about 100%; and from about 95% to about 100%.

As used herein, “about” when used in reference to a percentage of the area means variation of 1%-5%, of 5%-10%, of 10%-20%, and/or of 10%-50% (as a percent of the percentage of the area covered, or as a variation of the percentage of the area covered). For example, if the percentage of the area is “about 20%”, the percentage may vary 5%-10% as a percent of the percentage i.e. from 19% to 21% or from 18% to 22%; alternatively the percentage may vary 5%-10% as an absolute variation of the percentage i.e. from 15% to 25% or from 10% to 30%.

As such, when the electroadhesive film is defined as at least partially covering and connectable to the inferior surface of said cartridge, it is understood that the areas of coverage fall within these defined ranges.

In some embodiments, the electroadhesive gripping system further comprises a voltage connector coupled to said frame configured to provide an electrical connection receptacle between the power supply and the detachably connectable electroadhesive film voltage connector interface.

In some embodiments, the power supply is separable from the frame. In some embodiments, the power supply is remotely mounted off-board from the frame in a docking station.

In any one of the embodiments described herein, the power supply is configured to provide high voltage current. In any one of the embodiments described herein the power supply is configured to provide low voltage current. In any one of the embodiments described herein the power supply is configured to provide both high voltage and low voltage current.

In any one of the embodiments described herein, the power supply is configured to provide alternating current (AC) voltage. In any one of the embodiments described herein, the power supply is configured to provide direct current DC voltage.

As described herein, high voltage is defined as a range of DC voltage of any one or more of the following from 250 V to 8,000 V; from 500 V to 8,000 V; from 1,000 V to 8,000 V; from 1,500 V to 8,000 V; from 2,000 V to 8,000 V; from 3,000 V to 8,000 V; from 4,000 V to 8,000 V; from 5,000 V to 8,000 V; from 6,000 V to 8,000 V; from 7,000 V to 8,000 V; from 250 V to 1,000 V; from 250 V to 2,000 V; from 250 V to 4,000 V; from 500 V to 1,000 V; from 500 V to 2,000 V; from 500 V to 4,000 V; from 1,000 V to 2,000 V; from 1,000 V to 4,000 V; from 1,000 V to 6,000 V; from 2,000 V to 4,000 V; from 2,000 V to 6,000 V; from 4,000 V to 6,000 V; from 4,000 V to 8,000 V; and from 6,000 V to 8,000 V.

As described herein, high voltage is defined as a range of AC voltage of any one or more of the following from 250 Vᵣₘₛ to 8,000 Vᵣₘₛ; from 500 Vᵣₘₛ to 8,000 Vᵣₘₛ; from 1,000 Vᵣₘₛ to 8,000 Vᵣₘₛ; from 1,500 Vᵣₘₛ to 8,000 Vᵣₘₛ; from 2,000 Vᵣₘₛ to 8,000 Vᵣₘₛ; from 3,000 Vᵣₘₛ to 8,000 Vᵣₘₛ; from 4,000 Vᵣₘₛ to 8,000 Vᵣₘₛ; from 5,000 Vᵣₘₛ to 8,000 Vᵣₘₛ; from 6,000 Vᵣₘₛ to 8,000 Vᵣₘₛ; from 7,000 Vᵣₘₛ to 8,000 Vᵣₘₛ; from 250 Vᵣₘₛ to 1,000 Vᵣₘₛ; from 250 Vᵣₘₛ to 2,000 Vᵣₘₛ; from 250 Vₘ to 4,000 Vᵣₘₛ; from 500 Vᵣₘₛ to 1,000 Vᵣₘₛ; from 500 Vᵣₘₛ to 2,000 Vᵣₘₛ; from 500 Vᵣₘₛ to 4,000 Vᵣₘₛ; from 1,000 V to 2,000 Vᵣₘₛ; from 1,000 Vᵣₘₛ to 4,000 Vᵣₘₛ; from 1,000 V to 6,000 Vᵣₘₛ; from 2,000 Vᵣₘₛ to 4,000 Vᵣₘₛ; from 2,000 Vᵣₘₛ to 6,000 Vᵣₘₛ; from 4,000 Vᵣₘₛ to 6,000 Vᵣₘₛ; from 4,000 Vᵣₘₛ to 8,000 Vᵣₘₛ; and from 6,000 Vᵣₘₛ to 8,000 Vᵣₘₛ.

As described herein, high voltage is defined as a range of DC voltage of any one or more of the following from about 250 V to about 8,000 V; from about 500 V to about 8,000 V; from about 1,000 V to about 8,000 V; from about 1,500 V to about 8,000 V; from about 2,000 V to about 8,000 V; from about 3,000 V to about 8,000 V; from about 4,000 V to about 8,000 V; from about 5,000 V to about 8,000 V; from about 6,000 V to about 8,000 V; from about 7,000 V to about 8,000 V; from about 250 V to about 1,000 V; from about 250 V to about 2,000 V; from about 250 V to about 4,000 V; from about 500 V to about 1,000 V; from about 500 V to about 2,000 V; from about 500 V to about 4,000 V; from about 1,000 V to about 2,000 V; from about 1,000 V to about 4,000 V; from about 1,000 V to about 6,000 V; from about 2,000 V to about 4,000 V; from about 2,000 V to about 6,000 V; from about 4,000 V to about 6,000 V; from about 4,000 V to about 8,000 V; and from about 6,000 V to about 8,000 V.

As described herein, high voltage is defined as a range of AC voltage of any one or more of the following from about 250 Vᵣₘₛ to about 8,000 Vᵣₘₛ; from about 500 Vᵣₘₛ to about 8,000 Vᵣₘₛ; from about 1,000 Vᵣₘₛ to about 8,000 Vᵣₘₛ; from about 1,500 Vᵣₘₛ to about 8,000 Vᵣₘₛ; from about 2,000 Vᵣₘₛ to about 8,000 Vᵣₘₛ; from about 3,000 Vᵣₘₛ to about 8,000 Vᵣₘₛ; from about 4,000 Vᵣₘₛ to about 8,000 Vᵣₘₛ; from about 5,000 Vᵣₘₛ to about 8,000 Vᵣₘₛ; from about 6,000 Vᵣₘₛ to about 8,000 Vᵣₘₛ; from about 7,000 Vᵣₘₛ to about 8,000 Vᵣₘₛ; from about 250 Vᵣₘₛ to about 1,000 Vᵣₘₛ; from about 250 Vᵣₘₛ to about 2,000 Vᵣₘₛ; from about 250 Vᵣₘₛ to about 4,000 Vᵣₘₛ; from about 500 Vᵣₘₛ to about 1,000 Vᵣₘₛ; from about 500 Vᵣₘₛ to about 2,000 Vᵣₘₛ; from about 500 Vᵣₘₛ to about 4,000 Vᵣₘₛ; from about 1,000 Vᵣₘₛ to about 2,000 Vᵣₘₛ; from about 1,000 Vᵣₘₛ to about 4,000 Vᵣₘₛ; from about 1,000 Vᵣₘₛ to about 6,000 Vᵣₘₛ; from about 2,000 Vᵣₘₛ to about 4,000 Vᵣₘₛ; from about 2,000 Vᵣₘₛ to about 6,000 Vᵣₘₛ; from about 4,000 Vᵣₘₛ to about 6,000 Vᵣₘₛ; from about 4,000 Vᵣₘₛ to about 8,000 Vᵣₘₛ; and from about 6,000 Vᵣₘₛ to about 8,000 Vᵣₘₛ.

As described herein, low voltage is defined as a range of DC voltage of any one or more of the following from 2.0 V to 249.99 V; from 2.0 V to 150.0 V; from 2.0 V to 100.0 V; from 2.0 V to 50.0 V; from 5.0 V to 249.99 V; from 5.0 V to 150.0 V; from 5.0 V to 100.0 V; from 5.0 V to 50.0 V; from 50.0 V to 150.0 V; from 100.0 V to 249.99 V; from 100.0 V to 130.0 V; and from 10.0 V and 30.0 V.

As described herein, low voltage is defined as a range of AC voltage of any one or more of the following from 2.0 Vᵣₘₛ to 249.99 Vᵣₘₛ; from 2.0 Vᵣₘₛ to 150.0 Vᵣₘₛ; from 2.0 Vᵣₘₛ to 100.0 Vᵣₘₛ; from 2.0 Vᵣₘₛ to 50.0 Vᵣₘₛ; from 5.0 Vᵣₘₛ to 249.99 Vᵣₘₛ; from 5.0 Vᵣₘₛ to 150.0 Vᵣₘₛ; from 5.0 Vᵣₘₛ to 100.0 Vᵣₘₛ; from 5.0 Vᵣₘₛ to 50.0 Vᵣₘₛ; from 50.0 Vᵣₘₛ to 150.0 Vᵣₘₛ; from 100.0 Vᵣₘₛ to 249.99 Vᵣₘₛ; from 100.0 Vᵣₘₛ to 130.0 Vᵣₘₛ; and from 10.0 Vᵣₘₛ and 30.0 Vᵣₘₛ.

As described herein, low voltage is defined as a range of DC voltage of any one or more of the following from about 2.0 V to about 249.99 V; from about 2.0 V to about 150.0 V; from about 2.0 V to about 100.0 V; from about 2.0 V to about 50.0 V; from about 5.0 V to about 249.99 V; from about 5.0 V to about 150.0 V; from about 5.0 V to about 100.0 V; from about 5.0 V to about 50.0 V; from about 50.0 V to about 150.0 V; from about 100.0 V to about 249.99 V; from about 100.0 V to about 130.0 V; and from about 10.0 V and 30.0 V.

As described herein, low voltage is defined as a range of AC voltage of any one or more of the following from about 2.0 Vᵣₘₛ to about 249.99 Vᵣₘₛ; from about 2.0 Vᵣₘₛ to about 150.0 Vᵣₘₛ; from about 2.0 Vᵣₘₛ to about 100.0 Vᵣₘₛ; from about 2.0 V to about 50.0 Vᵣₘₛ; from about 5.0 Vᵣₘₛ to about 249.99 Vᵣₘₛ; from about 5.0 Vᵣₘₛ to about 150.0 Vᵣₘₛ; from about 5.0 Vᵣₘₛ to about 100.0 Vᵣₘₛ; from about 5.0 Vᵣₘₛ to about 50.0 Vᵣₘₛ; from about 50.0 Vᵣₘₛ to about 150.0 Vᵣₘₛ; from about 100.0 Vᵣₘₛ to about 249.99 Vᵣₘₛ; from about 100.0 Vᵣₘₛ to about 130.0 Vᵣₘₛ; and from about 10.0 Vᵣₘₛ and 30.0 Vᵣₘₛ.

The term “about” when used with respect to AC or DC voltage means variations of any of: up to 5%, up to 10%, up to 15%, up to 20%, up to 25%, and up to 30%. For example, if the amount of voltage is “about 120 V or 120 Vᵣₘₛ,” this may include variations of up to 5%, i.e.: 114 V to 126 V or 114 Vᵣₘₛ to 126 Vᵣₘₛ; variations of up to 10%, i.e.: 108 V to 132V or 108 Vᵣₘₛ to 132 Vᵣₘₛ variations of up to 15%, i.e.: 102 V to 138 V or 102 Vᵣₘₛ to 138 Vᵣₘₛ; variations of up to 20%, i.e.: 96 V to 144 V or 96 Vᵣₘₛ to 144 Vᵣₘₛ; variations of up to 25%, i.e.: 90 V to 150 V or 90 Vᵣₘₛ to 150 Vᵣₘₛ: or variations of up to 30%, i.e.: 84 V to 156 V or 84 Vᵣₘₛ to 156 Vᵣₘₛ.

In any one of the embodiments described herein the power supply is configured to couple to the voltage connector with wire and wire connectors.

In some embodiments, the remotely mounted off-board power supply is configured to reduce the overall weight or size of the frame of the electroadhesive gripping system.

In some embodiments, the electroadhesive gripping system further comprises an electrically conductive film dispersed between the power supply and the superior surface of said frame, interfaced with a voltage connector, and configured to provide an electrical interface between the power supply and the electroadhesive film.

In some embodiments, the electrically conductive film further comprises a printed circuit board configuration.

In any one of the embodiments described herein, the voltage connector, the wire, the wired connection, the printed circuit board and the electrically conductive film are configured to conduct high voltage current. In any one of the embodiments described herein, the voltage connector, the wire, the wired connection, the printed circuit board and the electrically conductive film are configured to conduct low voltage current. In any one of the embodiments described herein, the voltage connector, the wire, the wired connection, the printed circuit board and the electrically conductive film are configured to conduct both high voltage and low voltage current.

In some embodiments, the electrically conductive film is separable from the power supply and the superior surface of said frame.

In some embodiments, the electrically conductive film comprises two or more contact points for receiving applied voltage from said power supply.

In any one of the embodiments just described, the power supply further comprises two or more contact points for applying said voltage to said electrically conductive film.

Still further, in some embodiments, a contact point comprises: a pogo pin, a leaf spring, a carbon brush, a spring contact, a metallic contact button, a wiring connector, a wiring harness, a rare earth magnet, a ferrite magnet, an alnico magnet or a ferromagnetic contact.

In any one of the embodiments described herein, the electroadhesive gripping system further comprises a LED panel. In some embodiments, the LED panel is configured for placement between the frame and the cartridge.

In some embodiments of the electroadhesive gripping system, the cartridge is configured with mounting protrusions comprising attachment features for attaching the cartridge to the frame.

In some embodiments, the attachment features comprise: threads, mechanical fasteners, bayonette connections, magnetic interfaces, quick disconnect features and detachable fastening mechanisms.

In some embodiments, the mounting protrusions are at least partially transparent. In some embodiments, the mounting protrusions are at least partially translucent.

As described herein, transparent is defined as allowing a range of available lumens capable of being produced by a local light source, from 75% to 100%; from 80% to 100%; from 85% to 100%; from 90% to 100%; and from 95% to 100%, to pass through the mounting protrusions. Alternatively, transparent is defined as allowing a range of available lumens capable of being produced by a local light source, from about 75% to about 100%; from about 80% to about 100%; from about 85% to about 100%; from about 90% to about 100%; and from about 95% to about 100%, As further described herein, translucent is defined as allowing a range of available lumens capable of being produced by a local light source, from 25% to 74.99%; from 30% to 74.99%; from 35% to 74.99%; from 40% to 74.99%; from 45% to 74.99%; from 50% to 74.99%; from 55% to 74.99%; from 60% to 74.99%; from 65% to 74.99%; and from 70% to 74.99% to pass through the mounting protrusions. Alternatively, translucent is defined as allowing a range of available lumens capable of being produced by a local light source, from about 25% to about 74.99%; from about 30% to about 74.99%; from about 35% to about 74.99%; from about 40% to about 74.99%; from about 45% to about 74.99%; from about 50% to about 74.99%; from about 55% to about 74.99%; from about 60% to about 74.99%; from about 65% to about 74.99%; and from about 70% to about 74.99% to pass through the mounting protrusions.

As used herein, “about” when used in reference to lumens means variation of 1%-5%, of 5%-10%, of 10%/0-20%, and/or of 10%-50% (as a percent of the percentage of the lumens, or as a variation of the percentage of the lumens). For example, if the lumens percentage is “about 20%”, the percentage may vary 5%-10% as a percent of the percentage i.e. from 19% to 21% or from 18% to 22%; alternatively the percentage may vary 5%-10% as an absolute variation of the percentage i.e. from 15% to 25% or from 10% to 30%.

A local light source can be provided by the LED panel, a camera, an internal or external lighting system or other optical system configured to interface with the electroadhesive gripping system.

In some embodiments of the electroadhesive gripping system, light from the LED panel passes through the mounting protrusions to illuminate objects below the cartridge.

In some embodiments of the electroadhesive gripping system, the cartridge comprises a multi-layer construction, wherein the layers are either permanently or detachably bonded together with materials comprising: glue, epoxy, double-sided tape, magnetic attachment and mechanical attachment means, to be described in further detail below.

In some embodiments, the cartridge layers and components comprise: electroadhesive film, polyethylene sheet, polyurethane foam, glass plate, shatter-proof glass, plastic plates, plastic films, plastic sheets, metallic plates, polyethylene terephthalate (PET) film, double-stick tape, silicone, epoxies, spray adhesives and mechanical attachment features.

In some embodiments of the electroadhesive gripping system, the cartridge layers and components consist of: electroadhesive film, polyethylene foam, glass plate, shatterproof glass, acrylic, p polyethylene terephthalate (PET) film, polyurethane sheet, epoxies, double stick tapes; and mechanical attachment features.

In some embodiments of the electroadhesive gripping system, the electrically conductive film is electrically insulated from said frame.

In some embodiments of the electroadhesive gripping system, the electrically conductive film further comprises a printed circuit board.

In some embodiments, the printed circuit board comprises a mounted voltage connector is configured to detachably interface with the electroadhesive film voltage connector interface.

In some embodiments of the electroadhesive gripping system, the voltage connector interface further comprises a reinforcing card, configured to receive the end of the electroadhesive film comprising electrical traces from the one or more electrodes contained in the electroadhesive film.

In some embodiments, the reinforcing card is further configured to accurately align the electrical traces of the of the electroadhesive film with mating contacts on the printed circuit board of the voltage connector.

In some embodiments, the reinforcing card is further configured to provide a first component of a securing mechanism to removably secure the connection between the electroadhesive film voltage connector interface and the voltage connector.

In some embodiments of the electroadhesive gripping system, the voltage connector comprises a second component of a securing mechanism to removably secure the connection between the electroadhesive film voltage connector interface and the voltage connector.

In some embodiments, the voltage connector further comprises a compressible gasket to prevent electrical arcing when the electroadhesive film voltage connector interface is secured in the voltage connector.

In some embodiments, the compressible gasket comprises: paper reinforced phenolics, fluorinated ethylene propylene (FEP), neoprene, nylon, polyethylene terephthalate (PET or PETG), polyester such as Mylar, polystyrene, polysulfone, polyurethane, silicon rubber, vinyl and foam variations thereof.

In some embodiments, the voltage connector further comprises an insulating layer between the contact points of the electrical traces on the electroadhesive film to prevent electrical arcing between the electrical traces when the electroadhesive film voltage connector interface is secured in the voltage connector.

In some embodiments of the electroadhesive gripping system, the voltage connector interface further comprises an insulating layer between electrical traces from the one or more electrodes on the electroadhesive film to prevent electrical arcing between the electrical traces when the electroadhesive film voltage connector interface is secured in the voltage connector.

In some embodiments of the system, the insulting layer comprises: acrylonitrile, butadiene, and styrene (A.B.S.), acetate, acrylic, ceramics, glass ceramics, woven glass laminates, Delrin, epoxy/fiberglass laminate, fiberglass laminate, fluorinated ethylene propylene (FEP), high-impact polystyrene (HIPS), polyimide, polyimide film, unfilled polyimide, aromatic polyamide, polyvinylidene difluoride (PVDF), mica, neoprene, nylon, PerFluoroAlkoxy (PFA), polyphenylene oxide and styrene blends (PPO), PolyEtherEther-Ketone (PEEK), polyethylene terephthalate (PET or PETG), polyester (Mylar), phenolics, polycarbonates, polystyrene, polyolefins, polysulfone, polyurethane, polytetrafluoroethylene (PTFE), polyvinylchloride (PVC), polystyrene, polyphenylene sulfide (PPS), silicon rubber, silicon/fiberglass, polyphenylene sulfide (PPS), polyetherimide (PEI), vinyl, electrical insulating papers and electrical insulating tapes, or a combination thereof.

### INCORPORATION BY REFERENCE

All publications, patents, and patent applications mentioned in this specification are herein incorporated by reference to the same extent as if each individual publication, patent, or patent application was specifically and individually indicated to be incorporated by reference.

### BRIEF DESCRIPTION OF THE DRAWINGS

The novel features of the invention are set forth with particularity in the appended claims. A better understanding of the features and advantages of the present invention will be obtained by reference to the following detailed description that sets forth illustrative embodiments, in which the principles of the invention are utilized, and the accompanying drawings of which:

FIG. 1A is a side cross-section of an example electroadhesive device.

FIG. 1B illustrates in side cross-sectional view the example electroadhesive device of FIG. 1A adhered to a foreign object

FIG. 1C illustrates in side cross-sectional close-up view an electric field formed in the foreign object of FIG. 1B as result of the voltage difference between electrodes in the adhered example electroadhesive device

FIG. 2A illustrates in side cross-sectional view an example pair of electroadhesive gripping surfaces having single electrodes thereon.

FIG. 2B illustrates in side cross-sectional view the example pair of electroadhesive gripping surfaces of FIG. 2A with voltage applied thereto.

FIG. 3A illustrates in top perspective view an example electroadhesive gripping surface in the form of a sheet with electrodes pattered on top and bottom surfaces thereof.

FIG. 3B illustrates in top perspective view another example electroadhesive gripping surface in the form of a sheet with electrodes patterned on the top and bottom surfaces thereof.

FIG. 3C illustrates in top perspective view another example electroadhesive gripping surface in the form of a sheet with electrodes patterned on the top and bottom surfaces thereof and also comprising an additional insulating layer to protect the electrodes.

FIG. 4A illustrates in a side section view an example electroadhesive gripping system comprising a representative frame with integral cartridge and film, and a separable power supply.

FIG. 4B illustrates in a side section view an example electroadhesive gripping system comprising a representative frame with side walls, an integral cartridge and film, and a separable power supply.

FIG. 4C illustrates in a side section view, an example cartridge with an integral intermediate deformable/conformable layer and film.

FIG. 4D illustrates in side view, an exploded assembly of a representative electroadhesive gripping system similar to FIGS. 4A and/or 4B.

FIG. 4E illustrates in plan view, one possible configuration of a connecting interface for an electroadhesive film

FIG. 5A illustrates in a side section view an example electroadhesive gripping system comprising a representative frame with a detached cartridge assembly and film, and an optionally separable power supply.

FIG. 5B illustrates in a side section view, an example electroadhesive gripping system comprising a detachable cartridge assembly with an intermediate deformable/conformable layer and film.

FIG. 6A is an illustrative isometric view of a power supply.

FIG. 6B is a representative illustration of an insulated contact point for a power supply.

FIG. 7A illustrates in a side section view an example electroadhesive gripping system with a representative frame illustrating one form of a detachable interface comprising an attachment mechanism such as a magnet, and a detachable cartridge assembly and film, with a detachable interface comprising a shim plate, and an optionally separable power supply.

FIG. 7B illustrates in a side section view an example detachable cartridge assembly with an intermediate deformable or conformable layer between the cartridge and the film, and a detachable interface comprising a shim plate.

FIG. 8A illustrates in a side section view an example electroadhesive gripping system with a representative frame illustrating another form of detachable interface comprising a first shim plate, and a detachable cartridge assembly and film, with a detachable interface comprising a second shim plate, and an optionally separable power supply.

FIG. 8B illustrates in a side section view an example electroadhesive gripping system with a representative frame illustrating another form of detachable interface comprising a first shim plate, and a detachable cartridge assembly with an intermediate deformable or conformable layer between the cartridge and the film, with a detachable interface comprising a second shim plate.

FIG. 9 illustrates a top perspective view of an alternative example of an electroadhesive gripping system comprising a representative frame cartridge and a power supply.

FIG. 10A illustrates an exploded perspective view of the electroadhesive gripping system shown in FIG. 9.

FIG. 10B illustrates an inferior perspective view of an illustrative cartridge comprising an electroadhesive film, the electrodes and voltage connector interface.

FIG. 10C illustrates a superior perspective view of an illustrative cartridge comprising the superior mounting surface and mounting protrusions.

FIG. 11 illustrates an exploded perspective view of the electroadhesive gripping system shown in FIG. 9, further comprising a LED panel.

FIGS. 12A and 12B illustrate two perspective views of the power supply and illustrative example of the electrically conductive film and a voltage connector.

FIG. 13 illustrates a perspective view of an illustrative example of an off-board power supply arrangement configured to provide power to a cartridge and an electroadhesive film in an illustrative frame.

FIG. 14 illustrates an example of a voltage connector and an electroadhesive film voltage connector interface.

FIG. 15 illustrates an example of possible assembly method for a voltage connector and an electroadhesive film voltage connector interface.

### DETAILED DESCRIPTION OF THE INVENTION

In the following detailed description, reference is made to the accompanying figures, which form a part hereof. In the figures, similar symbols typically identify similar components, unless context dictates otherwise. The illustrative embodiments described in the detailed description, figures, and claims are not meant to be limiting. Other embodiments may be utilized, and other changes may be made, without departing from the scope of the subject matter presented herein. It will be readily understood that the aspects of the present disclosure, as generally described herein, and illustrated in the figures, can be arranged, substituted, combined, separated, and designed in a wide variety of different configurations, all of which are explicitly contemplated herein.

An electroadhesive surface can include electrodes that are configured to induce an electrostatic attraction with nearby objects upon application of voltage to the electrodes. Systems described herein may also employ a load-bearing frame that is coupled to an electroadhesive gripping surface in combination with a cartridge. The cartridge and associated cartridge sub-assemblies, provide the system with flexible modular options for component sub-assembly configurations that can improve performance, increase system functionality, reduce maintenance and operational expenses, and provide more flexible uses in a variety of different product applications, all within one system.

The cartridge concept reduces maintenance costs by reducing the amount of time and individual component costs associated with repairing or replacing a single sub-component of a system versus a major component, or the entire system, when only a sub-component has failed within the system.

Additionally, the cartridge and the various assembly options, provides the user with a flexible range of configurations that can be utilized within a manufacturing process, or multiple assembly lines having a variety of parts. One core system (a “permanent” frame) can be utilized in multiple locations with a variety of different cartridge assembly configurations. This type of configuration lends itself to Just-In-Time (JIT) manufacturing and low-volume production manufacturing with quick production turn-over cycles.

As the term is used herein, “electro-adhesion” refers to the mechanical coupling of two objects using electrostatic forces. Electro-adhesion as described herein uses electrical control of these electrostatic forces to permit temporary and detachable attachment between a foreign substrate and a pick-up surface of an electro-adhesion-enabled pick-up tool. This electrostatic adhesion holds the foreign substrate and the pick-up surface together or increases the traction or friction between the foreign substrate and the surface of the pick-up plate due to electrostatic forces created by an applied electric field. The surface of the pick-up plate is placed against or nearby a surface of a foreign substrate. An electrostatic adhesion voltage is then applied via electrodes using external control electronics in electrical communication with the electrodes. The electrostatic adhesion voltage uses alternating positive and negative charges on neighboring electrodes. As a result of the voltage difference between electrodes, one or more electro-adhesive forces are generated, which electro-adhesive forces act to hold the surface of the plate and the foreign substrate against one another. Due to the nature of the forces being applied, it will be readily appreciated that actual contact between the surface of the pick-up surface and the foreign substrate is not necessary. For example, a piece of paper, thin film, or other material or substrate may be placed between the pick-up surface of the plate and the foreign substrate. The electrostatic force maintains the current position of the pick-up surface of the plate relative to the surface of the foreign substrate. The overall electrostatic force may be sufficient to overcome the gravitational pull on the foreign substrate, such that the pick-up tool may be used to hold the foreign substrate aloft.

Removal of the electrostatic adhesion voltages from the electrodes ceases the electrostatic adhesion force between the pick-up surface of the plate and the surface of the foreign substrate. Thus, when there is no electrostatic adhesion voltage between electrodes, the pick-up tool can move readily relative to the surface of the foreign substrate. This condition allows the pick-up tool to move before and after an electrostatic adhesion voltage is applied. Well controlled electrical activation and de-activation enables fast adhesion and detachment, such as response times less than about 50 milliseconds, for example, while consuming relatively small amounts of power.

As the term is used herein, “pick-up surface”, “electroadhesion surface”, “gripper surface”, pick-up or gripping surface “blanket”, and variations thereof are intended to be synonymous, and refer to the electroadhesion film surface of the electroadhesion gripping system.

In an exemplary aspect, the pick-up surface of the system includes electrodes on an outside surface of an insulating material, or at or near the electroadhesion gripping surface of the electroadhesion film. This aspect is well suited for controlled attachment to insulating and weakly conductive inner materials of various foreign substrates.

In other exemplary aspects, the electrodes may be embedded within an insulating material so as to provide insulation both between the electrodes, and between the electrodes and the foreign substrate. The insulating material may further comprise multiple separate layers of insulation, each providing different properties that are beneficial to the overall application.

As will be readily appreciated, a shorter distance between the surface of the pick-up plate and the surface of a foreign substrate results in a stronger electro-adhesive force between the objects. Accordingly, a deformable surface adapted to at least partially conform to the surface of the foreign substrate may be used.

As the term is used herein, an electrostatic adhesion voltage refers to a voltage that produces a suitable electrostatic force to couple the pick-up surface of the plate to a foreign substrate. The minimum voltage needed for the pick-up surface will vary with a number of factors, such as: the size of the pick-up surface, the material conductivity and spacing of electrodes, the insulating material, the foreign substrate material, the presence of any disturbances to electro-adhesion such as dust, other particulates or moisture, the weight of any substrates being supported by the electro-adhesive force, compliance of the electro-adhesive device, the dielectric and resistivity properties of the foreign substrate, and the relevant gaps between electrodes and the foreign substrate surface.

In some aspects, an electro-adhesive pick-up surface can take the form of a substantially planar panel or sheet having a plurality of electrodes thereon. In other aspects, the electro-adhesive pick-up surface may take a fixed shape that is matched to the geometry of the foreign substrate most commonly lifted or handled by the pick-up tool. The electrodes may be enhanced by various means, such as by being patterned on an adhesive device surface to improve electro-adhesive performance, or by making them using soft or flexible materials to increase compliance and thus conformance to irregular surfaces on foreign substrates.

In still other aspects the an electro-adhesive pick-up surface can take the form of a substantially planar panel or sheet having a plurality of electrodes thereon, resting over a cartridge having an intermediate layer or space or bladder that is deformable or conformable to rough or irregular surfaces or shapes of a foreign object. The ability to better conform the electroadhesive film to the rough or irregular surfaces or shapes of a foreign object improves the adhesion bond and performance of the system.

As the terms are used herein, deformable and conformable are intended to be interpreted synonymously; meaning: corresponding in form, compliant, ability to adapt; capable of being reshaped. And conversely, it is implied and directly suggested that these terms also mean the ability to return to their original shape, with in the elastic limits of the material.

The present disclosure relates in various embodiments to systems, devices and methods involving electroadhesive or electrostatic applications. In some embodiments, various electroadhesive or electrostatic systems or devices can include electrodes adapted to deliver an electrostatic force suitable to adhere separate objects together. Additionally, a secondary adhesion component, such as a base surface, may be included that facilitates the use of a secondary force or manner in addition to the electrostatic force to adhere the separate objects together. In some instances, such a base surface or other secondary adhesion component can include a soft pad material having multiple modes of adhesion to a foreign object. While the various examples disclosed herein focus on particular aspects of specific electroadhesive applications, it will be understood that the various principles and embodiments disclosed herein can be applied to other electrostatic applications and arrangements as well. In addition, while the various examples and discussions set forth herein often refer to a “secondary” force or component in addition to an electroadhesive force or components, it will be readily appreciated that such other forces or components need not be considered “secondary” in all instances. In some examples, it may be more appropriate to consider one type of forces or items as electrostatic or electroadhesive attraction forces or components, and another type of forces or items as separate attraction forces or components that are separate from the electrostatic or electroadhesive types. Such other attraction forces may be physical in nature, and as such can be referred to as physical attraction forces that can be used to augment the electrostatic or electroadhesion forces.

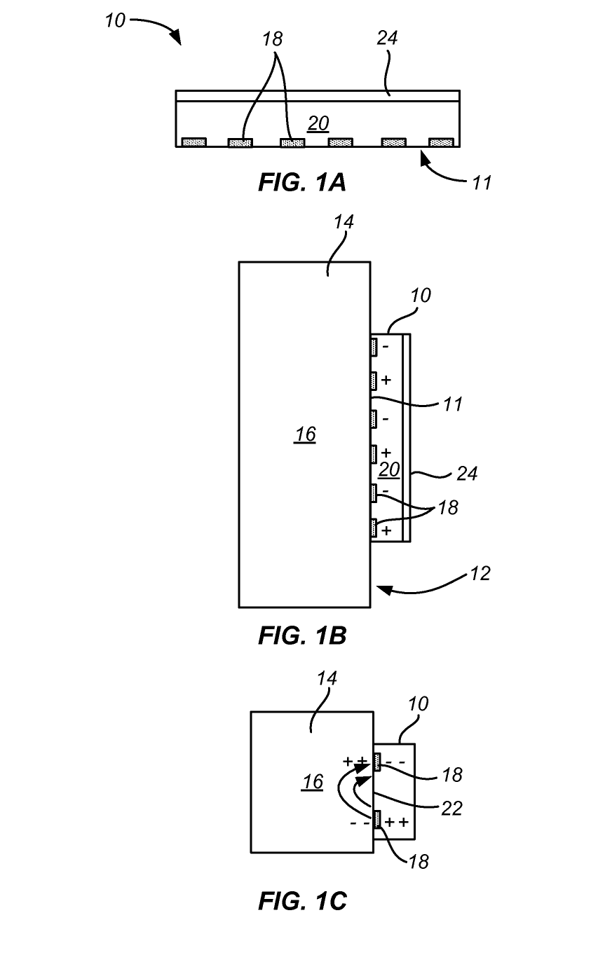

Turning first to FIG. 1A, an example electroadhesive device is illustrated in elevated cross-sectional view. Electroadhesive device 10 includes one or more electrodes 18 located at or near an “electroadhesive gripping surface” 11 thereof, as well as an insulating material 20 between electrodes and a backing 24 or other supporting structural component. In many cases, the insulating material 20 may extend outward from the electrode and be present between the electrodes and the foreign substrate. In some cases, the insulator 20 may actually be comprised of several different layers of insulators. For purposes of illustration, electroadhesive device 10 is shown as having six electrodes in three pairs, although it will be readily appreciated that more or fewer electrodes can be used in a given electroadhesive device. Where only a single electrode is used in a given electroadhesive device, a complimentary electroadhesive device having at least one electrode of the opposite polarity is preferably used therewith. With respect to size, electroadhesive device 10 is substantially scale invariant. That is, electroadhesive device sizes may range from less than 1 square centimeter to greater than several meters in surface area. Even larger and smaller surface areas are also possible, and may be sized to the needs of a given application.

FIG. 1B depicts in elevated cross-sectional view of the example electroadhesive device 10 of FIG. 1A adhered to a foreign object 14. Foreign object 14 includes surface 12 and inner material 16. Electroadhesive gripping surface 11 of electroadhesive device 10 is placed against or nearby surface 12 of foreign object 14. An electrostatic adhesion voltage is then applied via electrodes 18 using external control electronics (not shown) in electrical communication with the electrodes 18. As shown in FIG. 1B, the electrostatic adhesion voltage uses alternating positive and negative charges on neighboring electrodes 18. As a result of the voltage difference between electrodes 18, one or more electroadhesive forces are generated, which electroadhesive forces act to hold the electroadhesive device 10 and foreign object 14 to each other. Due to the nature of the forces being applied, it will be readily appreciated that actual contact between electroadhesive device 10 and foreign object 14 is not necessary. Rather sufficient proximity to allow the electric field based electroadhesive interaction to take place is all that is necessary. For example, a piece of paper, thin film, or other material or substrate may be placed between electroadhesive device 10 and foreign object 14. Furthermore, although the term “contact” is used herein to denote the interaction between an electroadhesive device and a foreign object, it will be understood that actual direct surface to surface contact is not always required, such that one or more thin objects such as an insulator, can be disposed between an device or electroadhesive gripping surface and the foreign object. In some embodiments such an insulator between the gripping surface and foreign object can be a part of the device, while in others it can be a separate item or device.

Additionally or alternatively, there may be a gap between the electroadhesive gripping surface and the object being gripped and this gap can be decreased upon activation of the electroadhesive force. For example, the electroadhesive force can cause the electroadhesive gripping surface to move closer to the exterior surface of the object being gripped so as to close the gap. Moreover, the electroadhesive attraction can cause the gripping surface to move toward the exterior surface of the object being gripped at multiple points across the surface area of the gripping surface. For example, the compliant gripping surface to conform can the exterior surface microscopically, mesoscopically, and/or macroscopically. Such local gap-closing by the gripping surface can thereby cause the gripping surface to (at least partially) conform to the exterior surface of the object. Electroadhesive gripping surfaces with sufficient flexibility to conform to local non-uniformities, surface imperfections and other micro-variations and/or macro-variations in exterior surfaces of objects are referred to herein as compliant gripping surfaces. However, it is understood that any of the gripping surfaces described herein may exhibit such compliance whether specifically referred to as compliant gripping surfaces or not.

FIG. 1C illustrates in elevated cross-sectional close-up view an electric field formed in the foreign object of FIG. 1B as a result of the voltage difference between electrodes in the adhered example electroadhesive device 10. While the electroadhesive device 10 is placed against foreign object 14 and an electrostatic adhesion voltage is applied, an electric field 22 forms in the inner material 16 of the foreign object 14. The electric field 22 locally polarizes inner material 16 or induces direct charges on material 16 locally opposite to the charge on the electrodes of the device 18 and thus causes electrostatic adhesion between the electrodes 18 (and device 10) and the induced charges on the foreign object 14. The induced charges may be the result of a dielectric polarization or from weakly conductive materials and electrostatic induction of charge. In the event that the inner material 16 is a strong conductor, such as copper for example, the induced charges may completely cancel the electric field 22. In this case the internal electric field 22 is zero, but the induced charges nonetheless still form and provide electrostatic force to the electroadhesive device.

Thus, the electrostatic adhesion voltage provides an overall electrostatic force, between the electroadhesive device 10 and inner material 16 beneath surface 12 of foreign object 14, which electrostatic force maintains the current position of the electroadhesive device relative to the surface of the foreign object. The overall electrostatic force may be sufficient to overcome the gravitational pull on the foreign object 14, such that the electroadhesive device 10 may be used to hold the foreign object aloft. In various embodiments, a plurality of electroadhesive devices may be placed against foreign object 14, such that additional electrostatic forces against the object can be provided. The combination of electrostatic forces may be sufficient to lift, move, pick and place, or otherwise handle the foreign object. Electroadhesive device 10 may also be attached to other structures and hold these additional structures aloft, or it may be used on sloped or slippery surfaces to increase normal or lateral friction forces.

Removal of the electrostatic adhesion voltages from electrodes 18 ceases the electrostatic adhesion force between electroadhesive device 10 and the surface 12 of foreign object 14. Thus, when there is no electrostatic adhesion voltage between electrodes 18, electroadhesive device 10 can move more readily relative to surface 12. This condition allows the electroadhesive device 10 to move before and after an electrostatic adhesion voltage is applied. Well controlled electrical activation and de-activation enables fast adhesion and detachment, such as response times less than about 50 milliseconds, for example, while consuming relatively small amounts of power.

Electroadhesive device 10 includes electrodes 18 on an outside surface 11 of an insulating material 20. This embodiment is well suited for controlled attachment to insulating and weakly conductive inner materials 16 of various foreign objects 14. Other electroadhesive device 10 relationships between electrodes 18 and insulating materials 20 are also contemplated and suitable for use with a broader range of materials, including conductive materials. For example, a thin electrically insulating material (not shown) can be located on the surfaces of the electrodes.

Multiple insulating surfaces may also be used in certain cases, (such as illustrated by layer 49 in FIG. 3C), and the material on either side of the electrodes may be different from each other. As will be readily appreciated, a shorter distance between surfaces 11 and 12 as well as the material properties of such an electrically insulating material results in a stronger electroadhesive attraction between the objects due to the distance dependence of the field-based induced electroadhesive forces. Accordingly, a deformable surface 11 adapted to at least partially conform to the surface 12 of the foreign object 14 can be used.

As the term is used herein, an electrostatic adhesion voltage refers to a voltage that produces a suitable electrostatic force to couple electroadhesive device 10 to a foreign object 14. The minimum voltage needed for electroadhesive device 10 will vary with a number of factors, such as: the size of electroadhesive device 10, the material conductivity and spacing of electrodes 18, the insulating material 20, the foreign object material 16, the presence of any disturbances to electroadhesion such as dust, other particulates or moisture, the weight of any objects being supported by the electroadhesive force, compliance of the electroadhesive device, the dielectric and resistivity properties of the foreign object, and/or the relevant gaps between electrodes and foreign object surface. In one embodiment, the electrostatic adhesion voltage includes a differential voltage between the electrodes 18 that is between about 500 volts and about 15 kilovolts. Even lower voltages may be used in micro applications. In one embodiment, the differential voltage is between about 2 kilovolts and about 5 kilovolts. Voltage for one electrode can be zero. Alternating positive and negative charges may also be applied to adjacent electrodes 18. The voltage on a single electrode may be varied in time, and in particular may be alternated between positive and negative charge so as to not develop substantial long-term charging of the foreign object. The resultant clamping forces will vary with the specifics of a particular electroadhesive device 10, the material it adheres to, any particulate disturbances, surface roughness, and so forth. In general, electroadhesion as described herein provides a wide range of clamping pressures, generally defined as the attractive force applied by the electroadhesive device divided by the area thereof in contact with the foreign object.

The actual electroadhesion forces and pressure will vary with design and a number of factors. In one embodiment, electroadhesive device 10 provides electroadhesive attraction pressures between about 0.7 kPa (about 0.1 psi) and about 70 kPa (about 10 psi), although other amounts and ranges are certainly possible. The amount of force needed for a particular application may be readily achieved by varying the area of the contacting surfaces, varying the applied voltage, and/or varying the distance between the electrodes and foreign object surface, although other relevant factors may also be manipulated as desired.

Because an electrostatic adhesion force is the primary force used to hold, move or otherwise manipulate a foreign object, rather than a traditional mechanical or “crushing” force, the electroadhesive device 10 can be used in a broader set of applications. For example, electroadhesive device 10 is well suited for use with rough surfaces, or surfaces with macroscopic curvature or complex shape. In one embodiment, surface 12 includes roughness greater than about 100 microns. In a specific embodiment, surface 12 includes roughness greater than about 3 millimeters. In addition, electroadhesive device 10 can be used on objects that are dusty or dirty, as well as objects that are fragile. Objects of varying sizes and shapes can also be handled by one or more electroadhesive devices, as set forth in greater detail below.

### Electroadhesive Gripping Surfaces

Although electroadhesive device 10 having electroadhesive gripping surface 11 of FIG. 1A is shown as having six electrodes 18, it will be understood that a given electroadhesive device or gripping surface can have just a single electrode. Furthermore, it will be readily appreciated that a given electroadhesive device can have a plurality of different electroadhesive gripping surfaces, with each separate electroadhesive gripping surface having at least one electrode and being adapted to be placed against or in close proximity to the foreign object to be gripped. Although the terms electroadhesive device, electroadhesive gripping unit and electroadhesive gripping surface are all used herein to designate electroadhesive components of interest, it will be understood that these various terms can be used interchangeably in various contexts. In particular, while a given electroadhesive device might comprise numerous distinct gripping surfaces: these different gripping surfaces might also be considered separate “devices” or alternatively “end effectors” themselves. Embodiments with multiple different gripping surfaces may be considered as one single device or may also be considered as numerous different devices acting in concert.

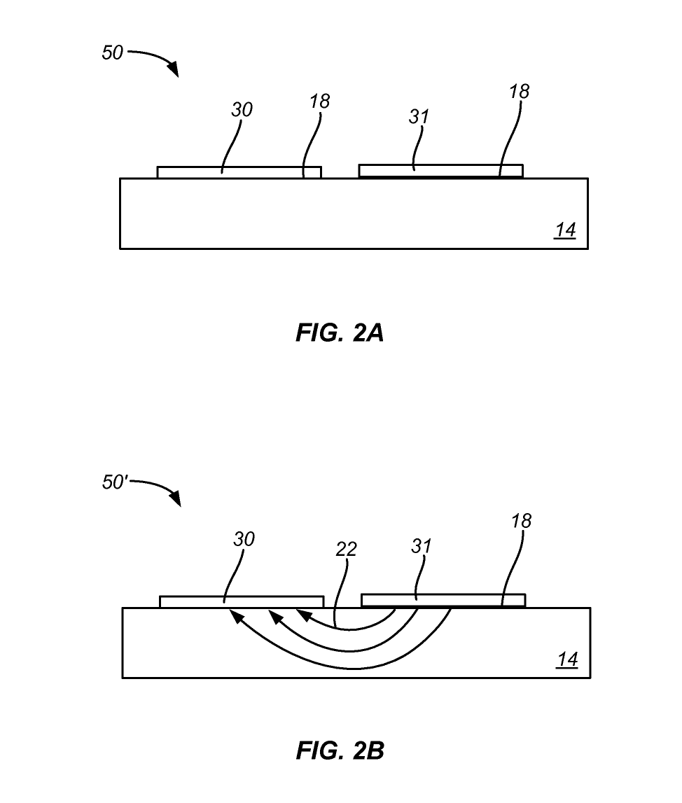

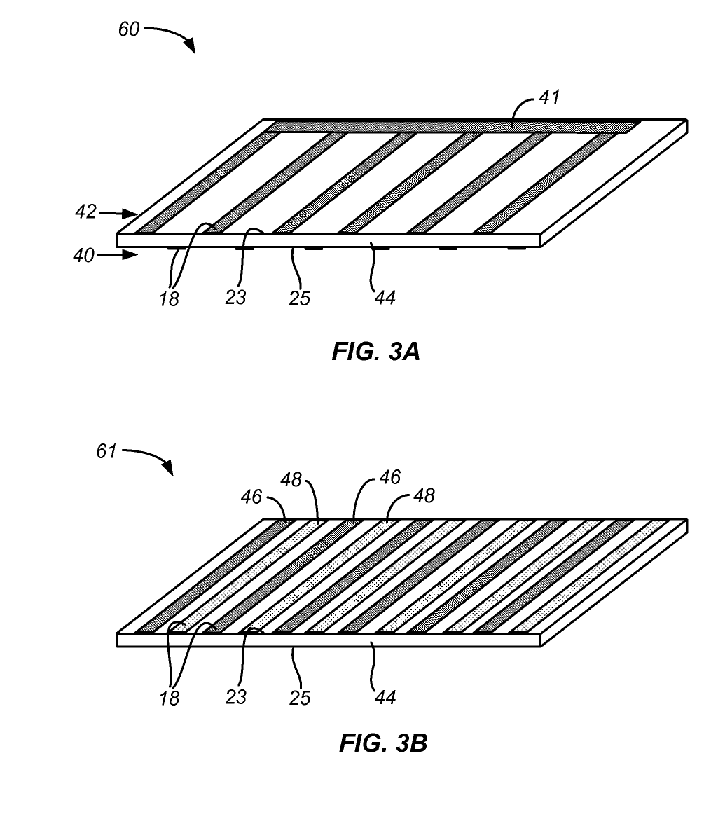

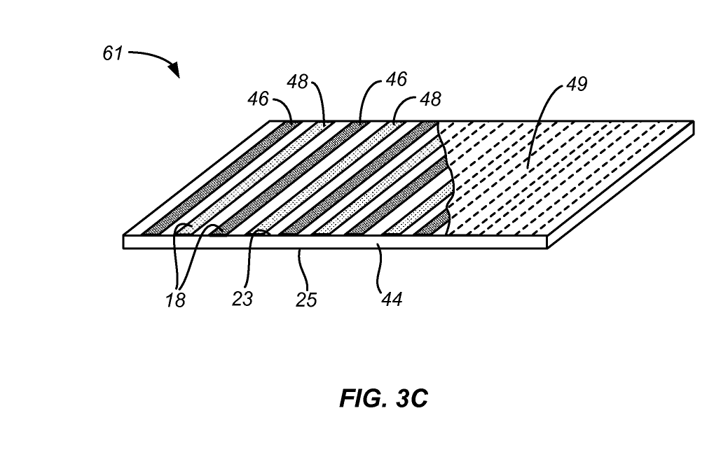

Referring to FIGS. 2A and 2B, an example pair of electroadhesive devices or gripping surfaces having single electrodes thereon is shown in side cross-sectional view. FIG. 2A depicts electroadhesive gripping system 50 having electroadhesive devices or gripping surfaces 30, 31 that are in contact with the surface of a foreign object 14, while FIG. 2B depicts activated electroadhesive gripping system 50′ with the devices or gripping surfaces having voltage applied thereto. Electroadhesive gripping system 50 includes two electroadhesive devices or gripping surfaces 30, 31 that directly contact the foreign object 14. Each electroadhesive device or gripping surface 30, 31 has a single electrode 18 coupled thereto. In such cases, the electroadhesive gripping system can be designed to use the foreign object as an insulation material. When voltage is applied, an electric field 22 forms within foreign object 14, and an electrostatic force between the gripping surfaces 30, 31 and the foreign object is created. Various embodiments that include numerous of these single electrode electroadhesive devices can be used, as will be readily appreciated.

In some embodiments, an electroadhesive gripping surface can take the form of a flat panel or sheet having a plurality of electrodes thereon. In other embodiments, the gripping surface can take a fixed shape that is matched to the geometry of the foreign object most commonly lifted or handled. For example, a curved geometry can be used to match the geometry of a cylindrical paint can or soda can. The electrodes may be enhanced by various means, such as by being patterned on an adhesive device surface to improve electroadhesive performance, or by making them using soft or flexible materials to increase compliance and thus conformance to irregular surfaces on foreign objects.

Turning next to FIGS. 3A-3C, two examples of electroadhesive gripping surfaces in the form of flat panels or sheets with electrodes patterned on surfaces thereof are shown in top perspective view. FIG. 3A shows electroadhesive gripping surface 60 in the form of a sheet or flat panel with electrodes 18 patterned on top and bottom surfaces thereof. Top and bottom electrodes sets 40 and 42 are interdigitated on opposite sides of an insulating layer 44. In some cases, insulating layer 44 can be formed of a stiff or rigid material. In some cases, the electrodes as well as the insulating layer 44 may be compliant and composed of a polymer, such as an acrylic elastomer, to increase compliance. In one preferred embodiment the modulus of the polymer is below about 10 MPa and in another preferred embodiment it is more specifically below about 1 MPa. Various known types of compliant electrodes are suitable for use with the devices and techniques described herein, and examples are described in U.S. Pat. No. 7,034,432, which is incorporated by reference herein in its entirety and for all purposes.

Electrode set 42 is disposed on a top surface 23 of insulating layer 44, and includes an array of linear patterned electrodes 18, (and may also include an additional outer insulating layer 49, as illustrated in FIG. 3C). A common electrode 41 electrically couples electrodes 18 in set 42 and permits electrical communication with all the electrodes 18 in set 42 using a single input lead to common electrode 41. Electrode set 40 is disposed on a bottom surface 25 of insulating layer 44, and includes a second array of linear patterned electrodes 18 that is laterally displaced from electrodes 18 on the top surface. Bottom electrode set 40 may also include a common electrode (not shown). Electrodes can be patterned on opposite sides of an insulating layer 44 to increase the ability of the gripping surface 60 to withstand higher voltage differences without being limited by breakdown in the air gap between the electrodes, as will be readily appreciated.

Alternatively, electrodes may also be patterned on the same surface of the insulating layer, such as that which is shown in FIG. 3B. As shown, electroadhesive gripping surface 61 comprises a sheet or flat panel with electrodes 18 patterned only on one surface thereof.

Electroadhesive gripping surface 61 can be substantially similar to electroadhesive gripping surface 60 of FIG. 3A, except that electrodes sets 46 and 48 are interdigitated on the same surface 23 of a compliant insulating layer 44. No electrodes are located on the bottom surface 25 of insulating layer 44. This particular embodiment decreases the distance between the positive electrodes 18 in set 46 and negative electrodes 18 in set 48, and allows the placement of both sets of electrodes on the same surface of electroadhesive gripping surface 61. Functionally, this eliminates the spacing between the electrodes sets 46 and 48 due to insulating layer 44, as in embodiment 60. It also eliminates the gap between one set of electrodes (previously on bottom surface 25) and the foreign object surface when the top surface 23 adheres to the foreign object surface. In some cases, the top (electrode) surface 23 may be further coated with an insulating material (as depicted by layer 49, and illustrated in FIG. 3C), so that the electrode sets 46 and 48 are completely sandwiched (e.g., encapsulated) between insulating materials. Although either embodiment 60 or 61 can be used, these changes in the latter embodiment 61 provide relatively greater electroadhesive forces between electroadhesive gripping surface 61 and the subject foreign object to be handled due to the closer proximity of both sets of electrodes 46, 48 to the foreign object surface.

In some embodiments, an electroadhesive device or gripping surface may comprise a sheet or veil type grasper that is substantially flexible in nature. In such embodiments, either no backing structure or a substantially flexible backing structure can be used, such that all or a portion of the veil type device or gripping surface can substantially flex or otherwise conform to a foreign object or objects, as may be desired for a given application. Creating electroadhesive grippers that facilitate such conforming or compliance to a foreign object can be achieved, for example, by forming the electroadhesive layer or gripping surface out of thin materials, by using foam or elastic materials, by butting out flaps or extensions from a primary electroadhesive sheet, or by connecting the sheet only at a few selected underlying locations, rather than to an entire rigid backing, among other possibilities.

Although the foregoing example embodiments for electroadhesive gripping surfaces in the form of flat panels or sheets depict bars or stripes for electrodes, it will be understood that any suitable pattern for electrodes could also be used for such a sheet-type electroadhesive gripping surface. For example, a sheet-type electroadhesive gripping surface could have electrodes in the form of discrete squares or circles that are distributed about the sheet and polarized in an appropriate manner, such as in an evenly spaced “polka-dot” style pattern. Other examples such as two sets of electrodes patterned as offset spirals can also be used. As one particular example, where a thin and flexible material is used for the insulating layer, such as a polymer, and where electrodes are distributed thereabout in the form of discrete discs, a resulting flexible and compliant electroadhesive gripping surface “blanket” would be able to conform to the irregular surfaces of a relatively large object while providing numerous different and discrete electroadhesive forces thereto during voltage application.

As yet another example, an intermediate baffle or bladder layer may be provided as a substantially flexible backing layer under a flexible and somewhat elastic electroadhesive gripping film layer. This substantially flexible backing layer should provide reversible conformability or deformability. Said conformable/deformable layer may comprise: foam, a polymer, an elastomeric material, or be in the form of a bladder. Still further the bladder may be a hydraulic or pneumatic bladder. Still further, the bladder may be filled with a compressible or loosely packed material, such as polymer beads, sand, Styrofoam, beans, husks or other similar material, that would provide compliance to the electroadhesive gripper film surface, allowing for better conformance to a non-smooth or non-flat foreign surface.

It will be understood that any suitable pattern for electrodes could also be used for such a flexible baffle-sheet-type electroadhesive gripping surface. For example, such a sheet-type electroadhesive gripping surface could utilize electrodes in the form of discrete squares or circles that are distributed about the sheet and polarized in an appropriate manner, such as in an evenly spaced “polka-dot” style pattern, or where electrodes are distributed thereabout in the form of discrete discs, a resulting flexible and compliant electroadhesive gripping surface “blanket” would be able to conform to the irregular surfaces of a relatively large object while providing numerous different and discrete electroadhesive forces thereto during voltage application.

Provided herein is an electroadhesive gripping system comprising: a frame having a superior surface and an inferior surface; a cartridge having a superior and inferior surface wherein the superior surface is detachably connectable to the inferior surface of said frame; an electroadhesive film with one or more electrodes at or near the gripping surface, and a backing surface of said electroadhesive film at least partially covering and connectable to the inferior surface of said cartridge, or optionally extending over a portion of the superior surface of said frame; and a power supply coupled to the superior surface of said frame, configured to apply voltage to the one or more electrodes of the electroadhesive film, wherein at least a portion of said connecting interface of said electroadhesive film is in direct contact with said power supply.

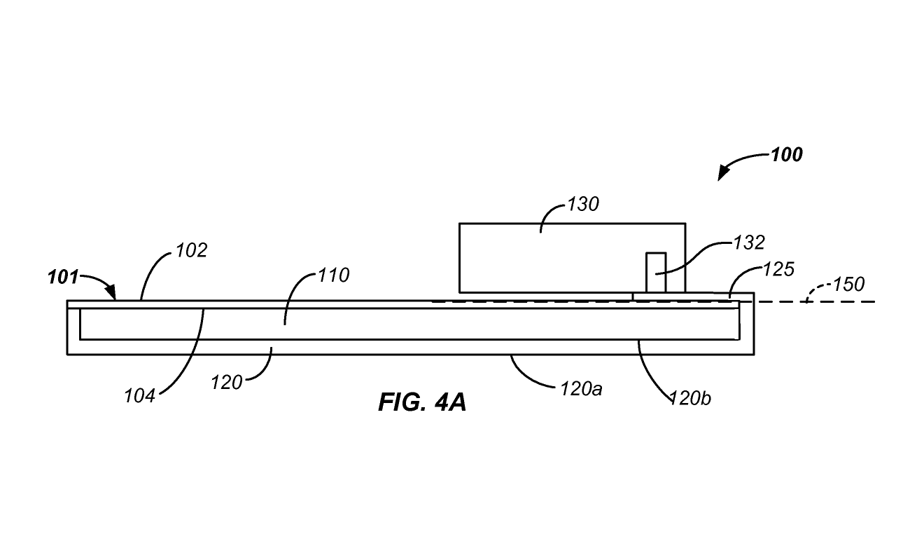

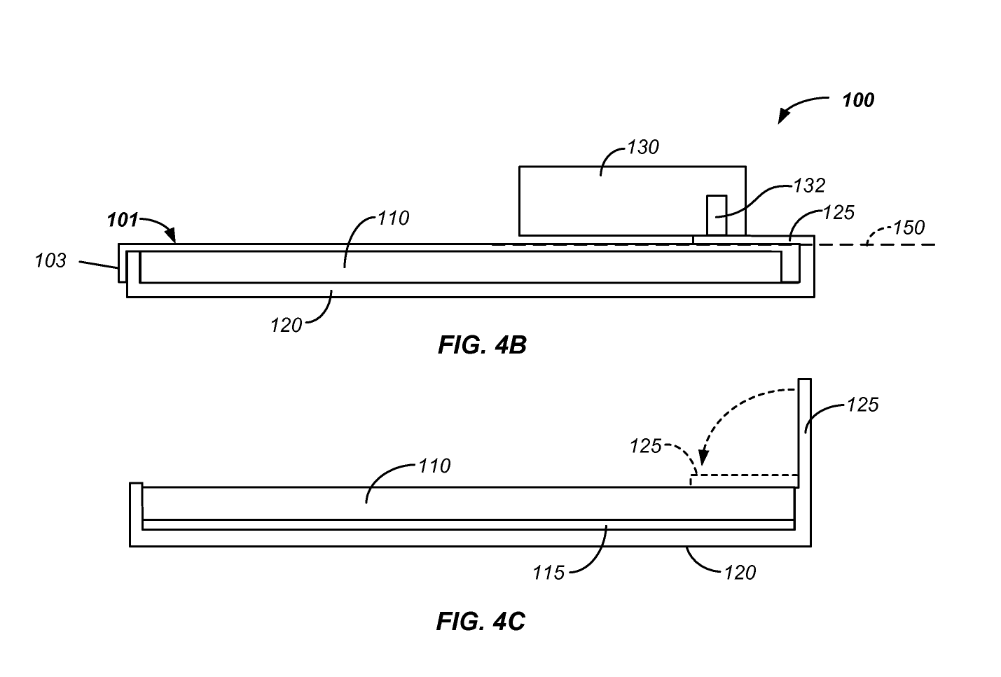

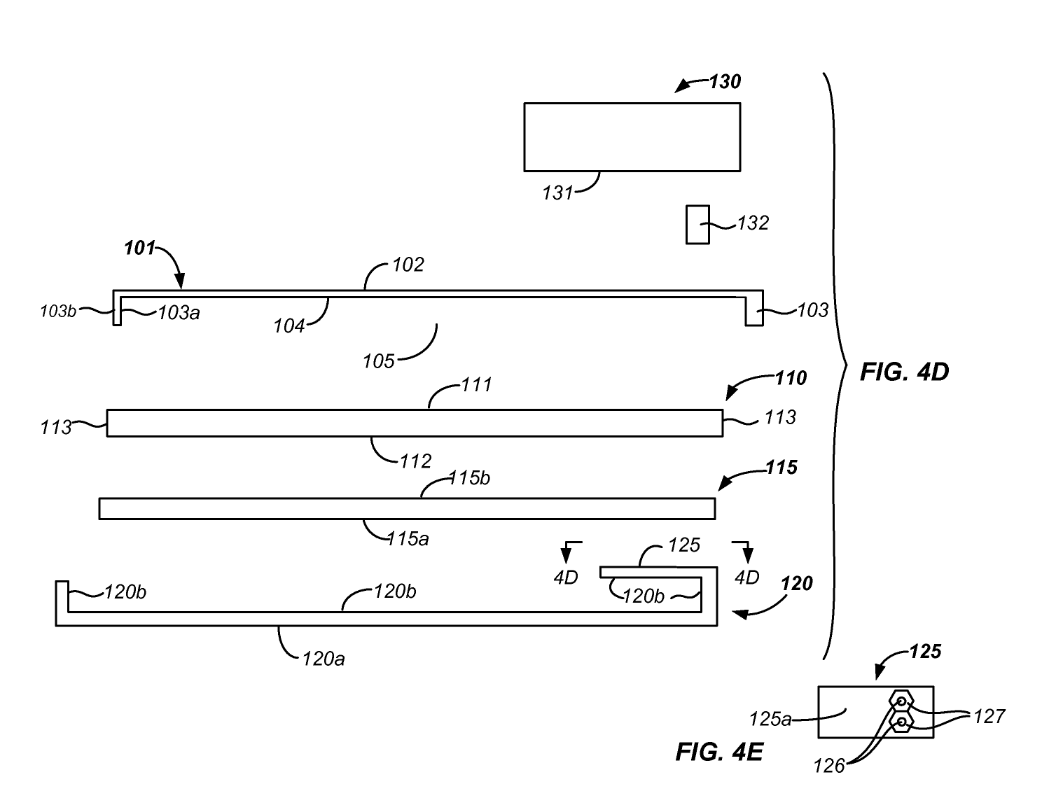

Referring next to FIGS. 4A through 4E which are illustrations of several variations of one version of the inventive modular electroadhesive gripping system. Illustrative details of the embodiment variations are delineated more clearly in the exploded detail of FIGS. 4D and 4E.

FIG. 4A is an example of an electroadhesive gripping system 100 comprising: a frame 101 having a superior surface 102, and an inferior surface 104; a cartridge 110 having a superior 111, inferior 112 and side surfaces 113, detachably connected to the inferior surface 104 of the frame 101; an electroadhesive film 120 with one or more electrodes (not shown) at or near the gripping surface 120a, and a backing surface 120b of said electroadhesive film 120, at least partially covering the inferior surface 112 of said cartridge 110, and at least a portion of said electroadhesive film comprising a connecting interface 125, in this case extends over at least a portion of the superior surface 102 of said frame; a power supply 130 coupled to the superior surface 102 of said frame 101, configured to apply voltage to the one or more electrodes of the electroadhesive film 120, wherein at least a portion of said connecting interface 125 of the electroadhesive film is interspersed between an inferior surface 131 of said power supply 130 and said superior surface 102 of said frame 101, creating a direct contact between the power supply and the connecting interface.

As described herein, in alternate embodiments (not shown) the superior and inferior surfaces of the frame may be incomplete surfaces, meaning that the surfaces may be partial surfaces resulting in an opening that creates a hollow space through the frame. For example, either the superior, or inferior, or both the superior and inferior surfaces of the frame may consist of an inwardly facing lip that runs completely around the frame on the planar surface that is the superior or inferior surface of the frame. The lip may be as small as 0.25 inches in width or may cover almost the entire surface.

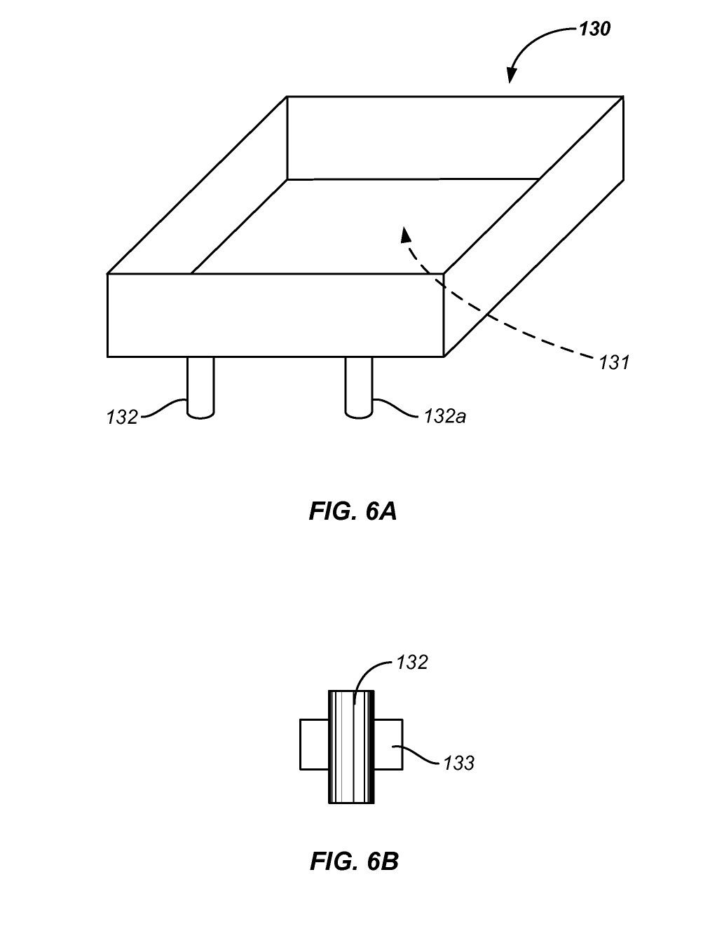

In this version of the illustration, there are no wires or connecting harnesses used or needed to transfer and apply power to the electrodes of the electroadhesive film. As illustrated herein and in FIGS. 4E and 6B, at least a pair of contact points 132 on the power supply 130 would be aligned with contact pads 126 on the connecting interface of the electroadhesive film 120 to transfer and apply power.

In some embodiments of the electroadhesive gripping system, the frame further comprises side walls comprising interior and exterior faces, creating a cavity within the frame between the inferior surface and the interior faces of said sides.

In some embodiments of the electroadhesive gripping system, the cartridge fits, at least partially, within, and conforms to the cavity of the frame.

FIG. 4B is an alternate example of an electroadhesive gripping system 100 shown in FIG. 4A, comprising: a frame 101 having a superior surface 102, sides 103 with interior 103a and exterior 103b faces, and an inferior surface 104, creating a cavity 105 within said frame 103 between said inferior surface 104 and the interior faces 103a, 103b of said sides; a cartridge 110 having a superior 111, inferior 112 and side surfaces 113 fitting at least partially within said cavity 105; an electroadhesive film 120 with one or more electrodes (not shown) at or near the gripping surface 120a, and a backing surface 120b of said electroadhesive film 120 wrapped around said frame 101, at least partially covering the inferior 112, side 113 and superior 111 surface of said cartridge 110, and the exterior faces 103b of said sides 103 of said frame 101, and wherein at least a portion of said electroadhesive film comprising a connecting interface 125, extends over the superior surface 102 of said frame; a power supply 130 coupled to the superior surface 102 of said frame 101, configured to apply voltage to the one or more electrodes of the electroadhesive film 120, wherein at least a portion of said connecting interface 125 of said electroadhesive film is interspersed between an inferior surface 131 of said power supply 130 and said superior surface 102 of said frame 101.

As in the FIG. 4A version, there are no wires or connecting harnesses used or needed to transfer and apply power to the electrodes of the electroadhesive film. As illustrated herein and in FIGS. 4E and 6B, at least a pair of contact points 132 on the power supply 130 would be aligned with contact pads 126 on the connecting interface of the electroadhesive film 120 to transfer and apply power.

In some embodiments, the electroadhesive gripping system further comprises a deformable or conformable layer dispersed between said cartridge and said electroadhesive film. FIG. 4C illustrates a comparable system with the addition of a conformable/deformable layer 115 sandwiched between the cartridge 110 and the electroadhesive film 120. The deformable foam, polymer, elastomeric material layer, a bladder or baffle layer may be provided as a substantially flexible backing layer under a flexible and somewhat elastic electroadhesive gripping film layer. It will be understood that a resulting flexible and compliant electroadhesive gripping surface “blanket” having discreet electrode patterns, and with a deformable/conformable layer beneath it, would be able to conform to the irregular surfaces of a relatively large object while providing numerous different and discrete electroadhesive forces thereto during voltage application.

The illustrations in 4A through 4E are the simplest form of modular system, requiring the power supply 130 to be removed before the various components within the electroadhesive gripper system can be serviced.

In some embodiments of the electroadhesive gripping system, the frame is load-bearing: Meaning the frame is capable of supporting loads heavier than the electroadhesive gripping system itself. In other embodiments, the frame is metallic. In still other embodiments the frame may be magnetic. In yet other embodiments, the frame may be non-metallic or electrically non-conductive. Each option provides potential advantages over another in a given manufacturing environment, or with a different set of sub-assembly components.

In some embodiments such as FIG. 4E of the electroadhesive gripping system, the electroadhesive film 120 comprising one or more electrodes (not shown) at or near the surface and having a connecting interface 125 also comprises contact pads 126 that connect to the one or more electrodes. The contact pads may comprise by way of non-limiting example: conductive areas or patterns; pogo pins; leaf springs; carbon brushes; spring contacts; metallic contact buttons 126a; wiring connectors; a wiring harness; rare earth magnets; ferrite magnets; alnico magnets; electromagnetic or ferromagnetic contacts.

In some embodiments of this illustrative example of the electroadhesive gripping system, the power supply 130 also comprises contact points 132 for connecting and transferring power to the contact pads 126 of the connecting interface 125 of the electroadhesive film 120 and transferring voltage to the electrodes, as illustrated in FIGS. 6A & 6B. The contact points may comprise by way of non-limiting example: pogo pins 132a; leaf springs; carbon brushes; spring contacts; metallic contact buttons; rare earth magnets; ferrite magnets; alnico magnets; electromagnetic or ferromagnetic contacts.

FIG. 6 illustrates just one possible arrangement of contact points 132, 132a on the inferior surface 131 of power supply 130.

In other embodiments to be detailed hereafter, the connecting interfaces between the power supply and the electroadhesive film may also include wiring connectors and/or a wiring harness on both components, in lieu of pogo pins; leaf springs; carbon brushes; spring contacts; metallic contact buttons; rare earth magnets; ferrite magnets; alnico magnets; electromagnetic or ferromagnetic contacts.

In still other embodiments, the connecting interfaces between the power supply and the electroadhesive film may include some combination of wiring connectors and/or a wiring harness between multiple components, in addition to pogo pins; leaf springs; carbon brushes; spring contacts; metallic contact buttons; rare earth magnets; ferrite magnets; alnico magnets; electromagnetic or ferromagnetic contacts. For example, there are configurations where there are likely to be more than one power supply required for the system and each power supply may require a different form of connective coupling due to its intended function and placement location on the system.

In still other embodiments, the contact pads 126 and/or contact points 132 comprise electrical insulators 127, 133 respectively. In other embodiments, the entire connecting interface 125 of the electroadhesive film 120 may be insulated from the frame 103.

In any one of the embodiments of the electroadhesive gripping system described herein, the power supply is separable from the frame.

Still further, any of the embodiments of the electroadhesive gripping system described herein comprise at least one attachment mechanism to retain the adjoining surfaces of the various components, at least partially, within intimate contact with each other. The various adjoining surfaces may include: the power supply and the frame; the power supply and the electroadhesive film connecting interface; the frame and the cartridge; the cartridge and the deformable layer; the cartridge and the electroadhesive film; the deformable layer and the electroadhesive film; the electroadhesive film and the frame; or the connecting interface and the frame.

As the term is used herein, dry adhesion or dry glue refers to an adhesion product based upon the adaptations of geckos' feet that allow them to climb sheer surfaces such as vertical glass. Synthetic equivalents use carbon nanotubes as synthetic setae on reusable adhesive patches.

In any one of the embodiments or adjoining surfaces described herein, the attachment mechanism may include: a chemical adhesive; such as an adhesive glue layer; a mechanical fastener; such as screws, bolts, nuts, rivets, etc; a heat fastener (e.g.: welded, spot welded, or spot-melted location); dry adhesion; such as dry glue, or soft sheeting held by Van der Waals forces or carbon nanotubes, (sometimes referred to as “artificial gecko”); Velcro; suction/vacuum adhesion; magnetic attachment or tape (e.g.: single- or double-sided). Depending on the degree of modularity desired or needed for a given situation, the attachment mechanism may create a permanent, temporary or even removable form of attachment.

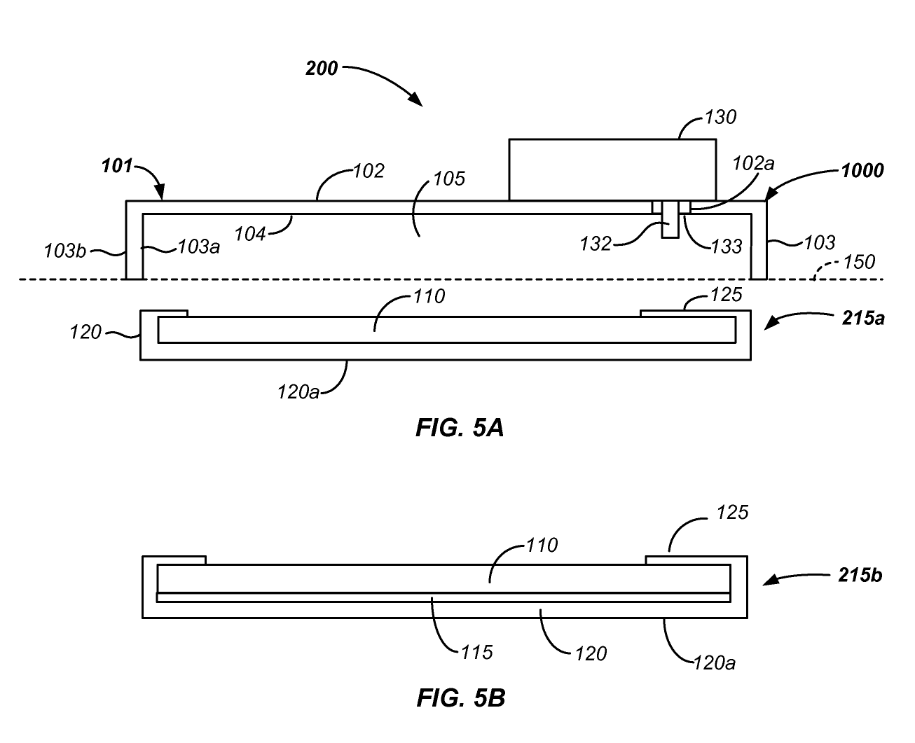

Referring now to FIGS. 5A & 5B are further extensions of the modular electroadhesive gripping system. Provided herein is an electroadhesive gripping system 200 comprising: in some aspects, a permanent frame assembly 1000, comprising a frame 101 having a superior surface 102, sides 103 with interior 103a and exterior 103b faces, and an inferior surface 104, creating a cavity 105 within said frame 101 between said inferior surface 104 and the interior faces 103a of said sides 103; a power supply 130 coupled to the superior surface 102 of said frame 101 comprising contact points 132 for transferring voltage, said contact points 132 protruding through an opening 102a in said frame 101; a cartridge 110 having a superior 111, inferior 112, and side 113 surfaces fitting at least partially within said frame cavity 105 comprising: an electroadhesive film 120 with one or more electrodes (not shown) at or near the gripping surface 120a, and a backing surface 120b of the electroadhesive film 120 wrapped around said cartridge 110, at least partially covering the inferior surface 112, side surfaces 113 and at least a portion of the top surface 111 of the cartridge, wherein at least a portion of said electroadhesive film 120 comprises a connecting interface 125 extending over a superior surface portion of the cartridge 111 situated beneath the power supply 130, wherein said connecting interface comprises 125 contact pads 126 that connect to the one or more electrodes, wherein said contact pads 126 interface with said contact points 132 of the power supply 130 protruding through the frame opening 102a when placed within said cavity 105 of said frame 101; and wherein said power supply 130 is configured to apply voltage to the one or more electrodes at or near the gripping surface 120a of the electroadhesive film 120.

Provided herein is an electroadhesive gripping system comprising an electroadhesive gripping system comprising: a frame having a superior surface and an inferior surface; a cartridge having a superior surface and inferior surface detachably connectable to said inferior surface of said frame; an electroadhesive film with one or more electrodes at or near a gripping surface, a backing surface at least partially covering and detachably connectable to the inferior surface of said cartridge and comprising a first connecting interface; a power supply comprising a second connecting interface configured to apply voltage to the one or more electrodes of the electroadhesive film through said second connecting interface.

In some embodiments of the electroadhesive gripping system, the connecting interface between the electroadhesive film and the power supply may be comprised of a wiring harness or similar quick-disconnect assembly mechanism in lieu of contact pads and contact points.

In some embodiments of the electroadhesive gripping system, the frame 101 is load-bearing: Meaning the frame is capable of supporting loads heavier than the electroadhesive gripping system frame itself. In other embodiments, the frame is metallic. In still other embodiments the frame may be magnetic. In yet other embodiments, the frame may be non-metallic or electrically non-conductive. As stated previously, each option provides potential advantages over another in a given manufacturing environment, or with a different set of sub-assembly components.

In some embodiments, the electroadhesive gripping system further comprises a deformable or conformable layer 115 dispersed between said cartridge 110 and said electroadhesive film 120. FIG. 5B illustrates a comparable system with the addition of a conformable/deformable layer 115 sandwiched between the cartridge 110 and the electroadhesive film 120. As stated previously, the deformable foam, polymer, elastomeric material layer, a bladder or baffle layer may be provided as a substantially flexible backing layer under a flexible and somewhat elastic electroadhesive gripping film layer. It will be understood that a resulting flexible and compliant electroadhesive gripping surface “blanket” having discreet electrode patterns, with a deformable/conformable layer beneath it would be able to conform to the irregular surfaces of a relatively large object while providing numerous different and discrete electroadhesive forces thereto during voltage application.

In some embodiments of the electroadhesive gripping system, the cartridge and said electroadhesive film combine as a separable cartridge sub-assembly 215a. In other embodiments, the cartridge, said deformable or conformable layer, and said electroadhesive film combine as yet another type of separable cartridge sub-assembly 215b.

In any one of the embodiments of the electroadhesive gripping system, the connecting interface of the electroadhesive film is electrically insulated from said frame when assembled.

In any one of the embodiments of the electroadhesive gripping system, the contact points 132 of the power supply 130 are electrically insulated 132a from said frame 101. In various embodiments, the contact points 132 may comprise by way of non-limiting example: pogo pins 132a; leaf springs; carbon brushes; spring contacts; metallic contact buttons; wiring connectors; a wiring harness; rare earth magnets; ferrite magnets; alnico magnets; or ferromagnetic contacts.

In a similar fashion, any of the embodiments of the electroadhesive gripper system, the contact pads 126 of the electroadhesive film connecting interface 125 are also electrically insulated.

In various embodiments, the contact pads 126 may comprise by way of non-limiting example: pogo pins; leaf springs; carbon brushes; spring contacts; metallic contact buttons 126a; wiring connectors; a wiring harness; rare earth magnets; ferrite magnets; alnico magnets; or ferromagnetic contacts. In still other embodiments, the entire connecting interface of the electroadhesive film may be insulated from the frame.

In any one of the embodiments of the electroadhesive gripping system described herein, the power supply is separable from the frame.

In some embodiments of the electroadhesive gripping system, alternative embodiments of the frame assembly 1000 as illustrated in FIG. 5A, 7A, or 8A could comprise a frame without sides or a cavity, as illustrated in FIG. 4A.

Still further, the connecting interface between the electroadhesive film and the power supply may be comprised of a wiring harness or similar quick-disconnect assembly mechanism in lieu of contact pads and contact points.

Additionally, depending on the requirements of the electroadhesive gripping system and the application for which it is intended, the system may have multiple power supply units to apply voltage to different components or sub-assembly units of the system at different times.

It would be apparent to one skilled in the art that multiple configurations of connecting interfaces may be applied to different power supply units within the same system, depending on the location of the power supply relative to the component being supplied by the power supply unit.

For example, a detachable power supply connected to the frame may utilize a wireless connecting interface with contact points and contact pads; whereas a remote power supply mounted on the base or robotic arm of the system may utilize a wiring harness or similar quick-disconnect system for applying power to a sub-assembly or component of the system where there is inadequate room for a power supply to be directly attached.

Still further, any of the embodiments of the electroadhesive gripping system described herein comprise at least one attachment mechanism to retain the adjoining surfaces of the various components, at least partially, within intimate contact with each other. The various adjoining surfaces may include: the power supply and the frame; the cartridge and the deformable layer; the deformable layer and the electroadhesive film, the cartridge and the connecting interface, or the cartridge and the electroadhesive film.

In any one of the embodiments or adjoining surfaces described herein, the attachment mechanism may include: a chemical adhesive; such as an adhesive glue layer; a mechanical fastener; such as screws, bolts, nuts, rivets, etc; a heat fastener (e.g.: welded, spot welded, or spot-melted location); a track based or mechanically nesting system, dry adhesion; such as dry glue, soft surfaces adhering using passive van der Waals forces or carbon nanotubes; Velcro; suction/vacuum adhesion; or tape (e.g.: single- or double-sided), magnetic or electromagnetic attachment.

Depending on the degree of modularity desired or needed for a given situation, the attachment mechanism may create a permanent, temporary or even removable form of attachment.

For example, it may be desirable for a mechanical fastener to attach the power supply to the frame, whereas it may be preferable to have any combination of permanent, temporary, or removable chemical adhesive between adjacent layers of the cartridge and conformable layer, cartridge and electroadhesive film, or conformable layer and electroadhesive film. In a similar fashion it may be appropriate to have heat fastened connections between various components such as insulators and contacts. Additionally, more conventional or cost-conservative attachment mechanisms such as tape, Velcro or even suction pads may be desired. Alternatively, more advanced methods of adhesion such as dry adhesion may be preferable in wet environments or where elaborate frame or component materials might require more creative or expensive attachment means.

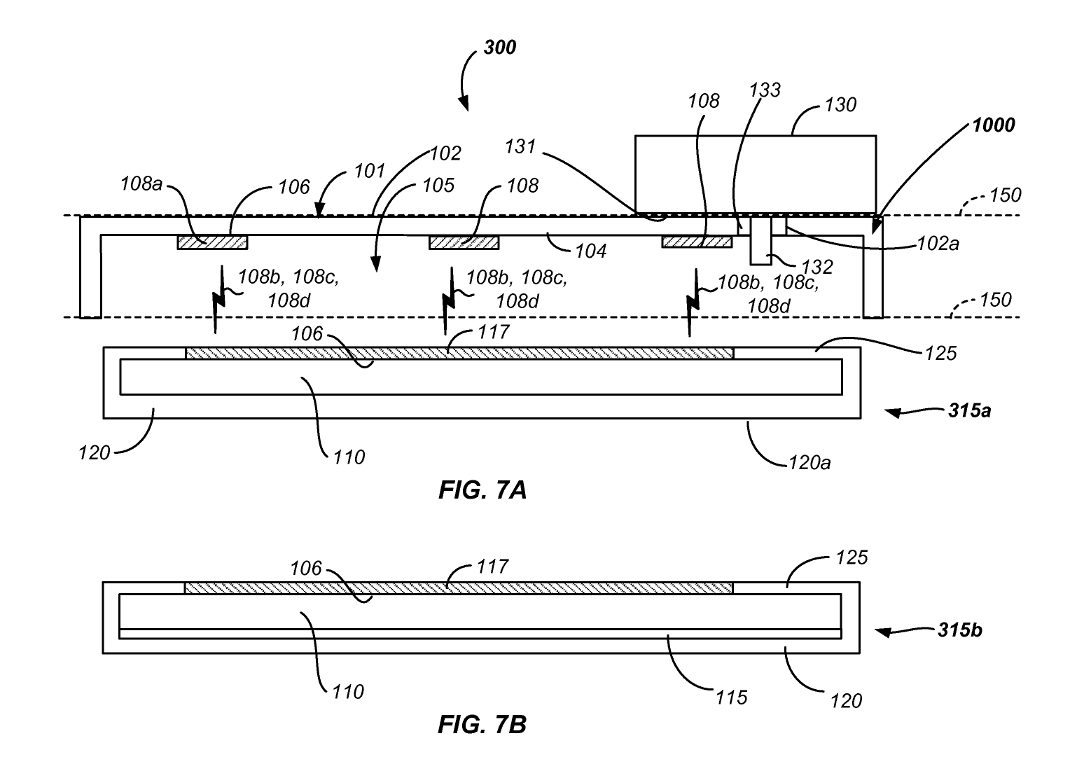

Referring now to FIGS. 7 & 8, one finds still other embodiments of modular electroadhesive gripping systems. Provided herein are variations of an electroadhesive gripping system comprising any of the configurations described herein, and further comprising at least one detachable interface 150.

As described herein, a detachable interface is any modular system connection point, intended to be easily separable for inspection, repair, or replacement. Such connection interface points are normally strategically designed and placed to easily allow an operator to manipulate the connection when necessary, but to remain and maintain a stable connection between two components when in normal use.

In some embodiments the detachable interface 150 is between the power supply 130 and frame 101 as illustrated in any of FIGS. 5, 7 & 8. In other embodiments the detachable interface 150 is between the permanent frame assembly 1000, or the frame 101 and the cartridge assembly 215, 315, 415 as illustrated in FIGS. 5, 7 & 8.

In some embodiments of the electroadhesive gripping system, the at least one detachable interface utilizes an attachment mechanism comprising at least one of: a chemical adhesive; a dry glue or dry adhesion fastening mechanism; a mechanical fastener; Velcro; tape; a magnet; or an electroadhesive surface. In some cases, when magnetic means are utilized, the magnets may comprise: a rare earth magnet; a ferrite magnet; an alnico magnet; an electromagnets; or a ferromagnetic contact. The attachment mechanism may pertain to the method of attaching the detachable interface to the gripping system components, or in some cases the attachment mechanism may pertain to the method of attaching the detachable interfaces themselves together.

In yet other embodiments of the electroadhesive gripping system, the at least one detachable interface further comprises a magnetic shim plate 117 on one assembly component and magnets on the opposing component. Still further the magnetic shim plate is coupled to the superior surface 111 of the cartridge 110 of the cartridge assy assembly 315 as shown in FIGS. 7 & 8. In other embodiments the magnetic shim plate is coupled to the inferior surface 104 of the frame 101. As with other component interfaces already described, an attachment mechanism such as: a chemical adhesive; a mechanical fastener; Velcro; tape; or a magnet may be utilized to adhere or couple the shim plate to the mating component surface.

As would be readily apparent to one skilled in the art, in some embodiments the shim plate may not be magnetic. In some embodiments the shim plate may be a metal plate; a non-metallic plate; or a non-magnetic plate. In each case, an appropriate attachment mechanism, such as those described above can be selected to create either a permanent or temporary form of attachment.

Still further, in other embodiments of the electroadhesive gripping system comprising a detachable interface with a shim plate, a second attachment mechanism may be utilized between said shim plate and the opposing coupling surface on the other side of the detachable interface. For example, the second attachment mechanism may comprise: a (temporary) chemical adhesive; a mechanical fastener; a magnet; dry adhesion; Velcro; suction/vacuum adhesion; or tape. Where magnetic means are utilized, the magnets may comprise: a rare earth magnet; a ferrite magnet; an alnico magnet; an electromagnets; or a ferromagnetic contact. As illustrated in FIG. 7A each component of the detachable interface has a means of attaching to its host attachment surface and a secondary attachment mechanism for removable attachment to its mating detachable interface on the opposing component. FIG. 7B illustrates a comparable system with the addition of a conformable/deformable layer 115 sandwiched between the cartridge 110 and the electroadhesive film 120. As stated previously, the deformable foam, polymer, elastomeric material layer, a bladder or baffle layer may be provided as a substantially flexible backing layer under a flexible and somewhat elastic electroadhesive gripping film layer. It will be understood that a resulting flexible and compliant electroadhesive gripping surface “blanket” having discreet electrode patterns, with a deformable/conformable layer beneath it would be able to conform to the irregular surfaces of a relatively large object while providing numerous different and discrete electroadhesive forces thereto during voltage application.

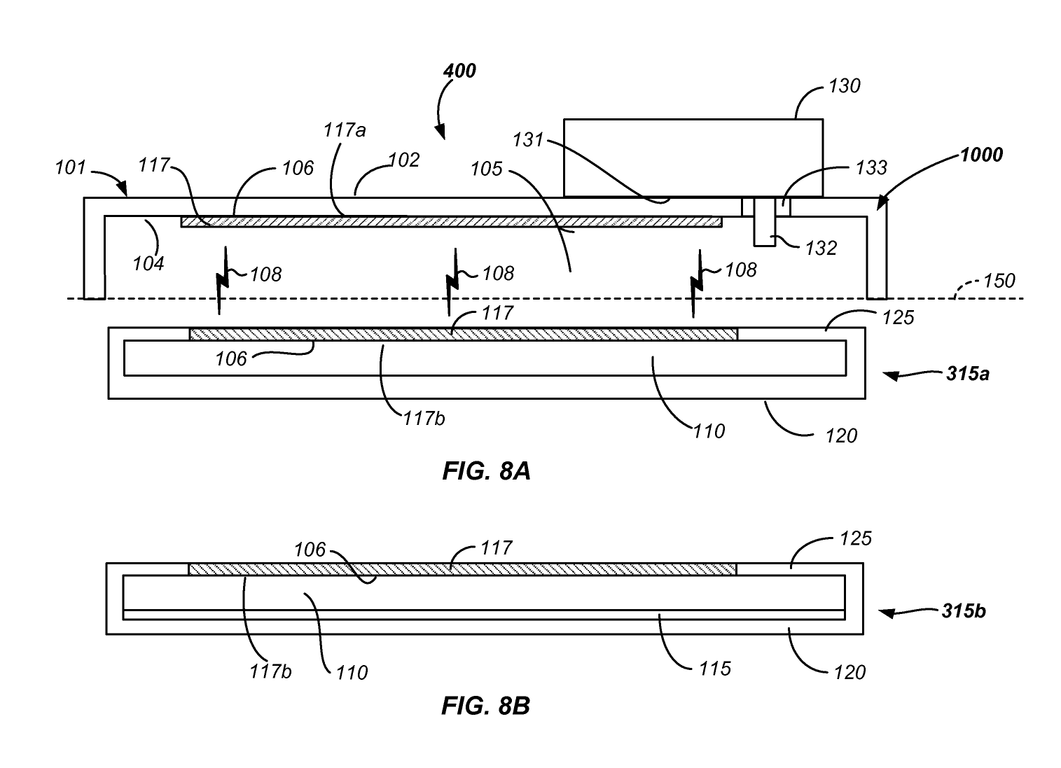

In still other embodiments, as illustrated in FIG. 8A, the detachable interface 150 may comprise two shim plates: wherein at least one side of the detachable interface comprises (at least one) first shim plate 117, wherein the superior surface 117a of the first shim plate 117 is coupled to the inferior surface 104 of the frame 101, and (at least one) second shim plate 117 (also shown in FIG. 8B), wherein the inferior surface 117b of the second shim plate 117 is coupled to the superior surface 111 of the cartridge 110 or cartridge assembly 315a or 315b. FIG. 8B illustrates a comparable system with the addition of a conformable/deformable layer 115 sandwiched between the cartridge 110 and the electroadhesive film 120. As stated previously, the deformable foam, polymer, elastomeric material layer, a bladder or baffle layer may be provided as a substantially flexible backing layer under a flexible and somewhat elastic electroadhesive gripping film layer. It will be understood that a resulting flexible and compliant electroadhesive gripping surface “blanket” having discreet electrode patterns, with a deformable/conformable layer beneath it would be able to conform to the irregular surfaces of a relatively large object while providing numerous different and discrete electroadhesive forces thereto during voltage application.

Still further, the at least one detachable interface comprising said at least one first shim plate 117 and at least one second shim plate 117 could comprise at least one of: a metal plate; a magnetic plate; a non-metallic plate; or a non-magnetic plate.

In any of the preceding shim plate embodiments having a detachable interface 150, there may exist yet another attachment mechanism 108 between the shim plates themselves comprising by way of non-limiting example, at least one of: magnets 108a; electrostatic adhesion; Van-der-Waals forces; dry adhesion; vacuum/suction; a temporary adhesive; a meltable adhesive; and a mechanical fastener.

In some embodiments, one skilled in the art would recognize that the power supply mechanism 130 of any one of the configurations described and configured for activating the electroadhesive film, may be the same or different from a power supply mechanism configured for activating electrostatic adhesion forces for the detachable interface comprising said first and second shim plates or the electrostatic adhesion force between the electroadhesive film and the cartridge. In other words, there may be two or more power supplies, each having a separate function.

As previously suggested, the power supply of any of the systems having a detachable interface may have a power supply that is separable from the frame. The means or method of separation of the power supply may or may not be the same as the detachable interface.

In any of the aforementioned embodiments, the electroadhesive gripping system may include a conformable/deformable layer between the cartridge and electroadhesive film. Said conformable/deformable layer may comprise: foam, a polymer, an elastomeric material, or a bladder. Still further the bladder may be a hydraulic or pneumatic bladder. Still further, the bladder may be filled with a compressible or loosely packed material, such as polymer beads, sand, Styrofoam, beans, husks or other similar material, that would provide compliance to the electroadhesive gripper film surface, allowing for better conformance to a non-smooth or non-flat foreign surface.

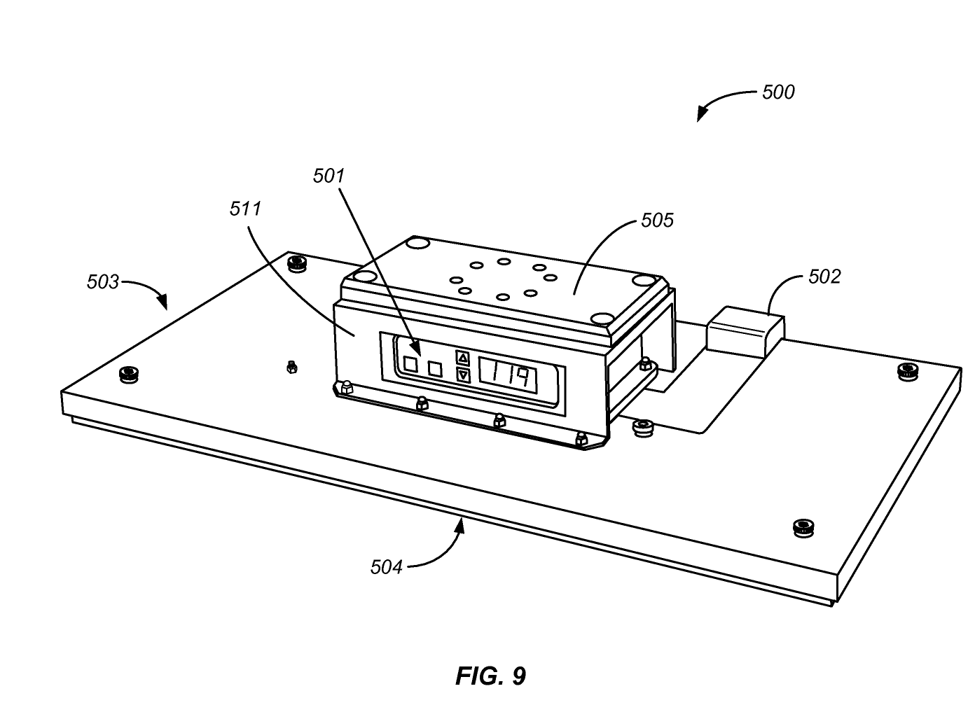

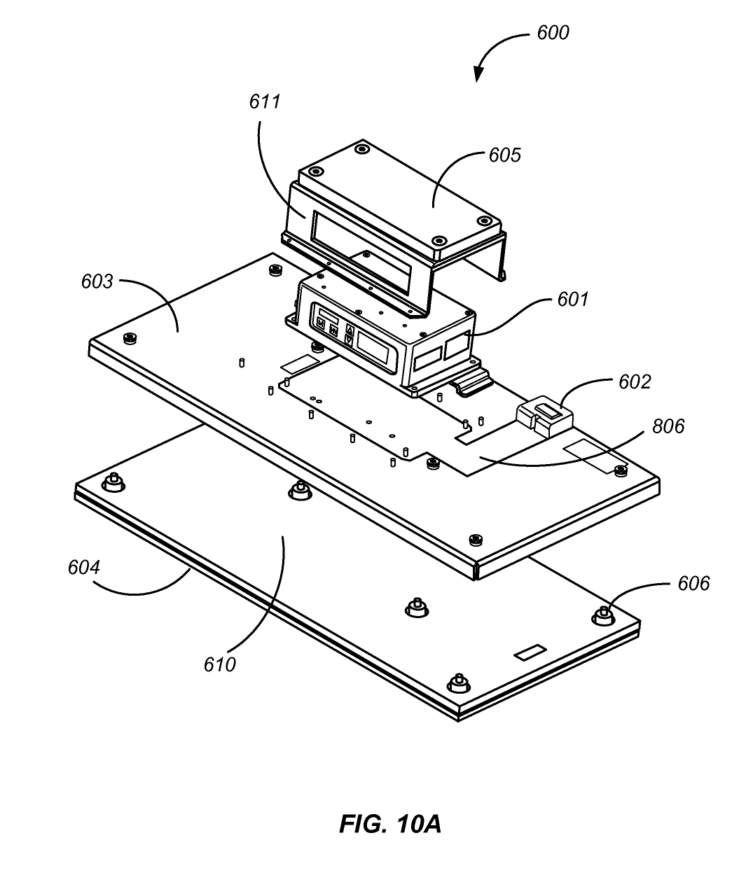

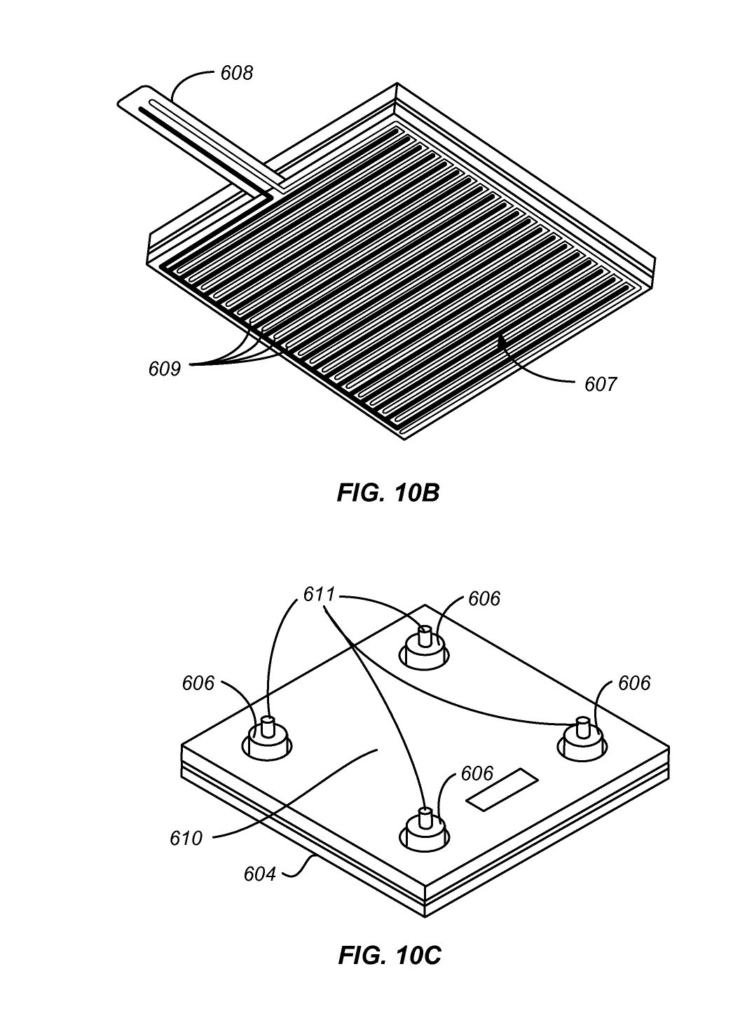

Provided herein is another embodiment of an electroadhesive gripping system 500, 600 as illustrated in FIGS. 9, 10A, 10B, and 10C, comprising a frame 503, 603 having a superior surface and an inferior surface; a cartridge 504, 604 having a superior surface 610 and inferior surface, wherein said superior surface is detachably connectable to said inferior surface of said frame; an electroadhesive film 607 comprising the gripping surface, with one or more electrodes 609 at or near the gripping surface, a backing on the surface electroadhesive film (not shown) at least partially covering and connectable to the inferior surface of said cartridge (not shown) and comprising a voltage connector interface 608; and a power supply 501 configured to apply voltage to the one or more electrodes 609 of the electroadhesive film 607.

In some embodiments, the electroadhesive film is configured to at least partially cover the inferior surface of said cartridge wherein the coverage is defined as a range of areas of any one or more of the following from 10% to 100%; from 20% to 100%; from 30% to 100%; from 40% to 100%; from 50% to 100%; from 60% to 100%; from 70% to 100%; from 80% to 100%; from 90% to 100%; and from 95% to 100%.

In some embodiments, the electroadhesive film is configured to at least partially cover the inferior surface of said cartridge wherein the coverage is defined as a range of areas of any one or more of the following from about 10% to about 100%; from about 20% to about 100%; from about 30% to about 100%; from about 40% to about 100%; from about 50% to about 100%; from about 60% to about 100%; from about 70% to about 100%; from about 80% to about 100%; from about 90% to about 100%; and from about 95% to about 100%.

As used herein, “about” when used in reference to a percentage of the area means variation of 1%-5%, of 5%-10%, of 10%-20%, and/or of 10%-50% (as a percent of the percentage of the area covered, or as a variation of the percentage of the area covered). For example, if the percentage of the area is “about 20%”, the percentage may vary 5%-10% as a percent of the percentage i.e. from 19% to 21% or from 18% to 22%; alternatively the percentage may vary 5%-10% as an absolute variation of the percentage i.e. from 15% to 25% or from 10% to 30%.

As such, when the electroadhesive film is defined as at least partially covering and connectable to the inferior surface of said cartridge, it is understood that the areas of coverage fall within these defined ranges.

In some embodiments, the electroadhesive gripping system further comprises a voltage connector 502, 602 coupled to said frame configured to provide an electrical connection receptacle between the power supply 501, 601 and the detachably connectable electroadhesive film voltage connector interface 608.

Also as noted in FIGS. 9 and 10A, a gripper mounting surface 505, 605,705 may be conveniently located on top of a housing 511, 611, 711 for the power supply 501, 601 701. In still other embodiments the gripper mounting surface 906 is mounted directly to the superior surface of the frame, as illustrated in FIG. 13.

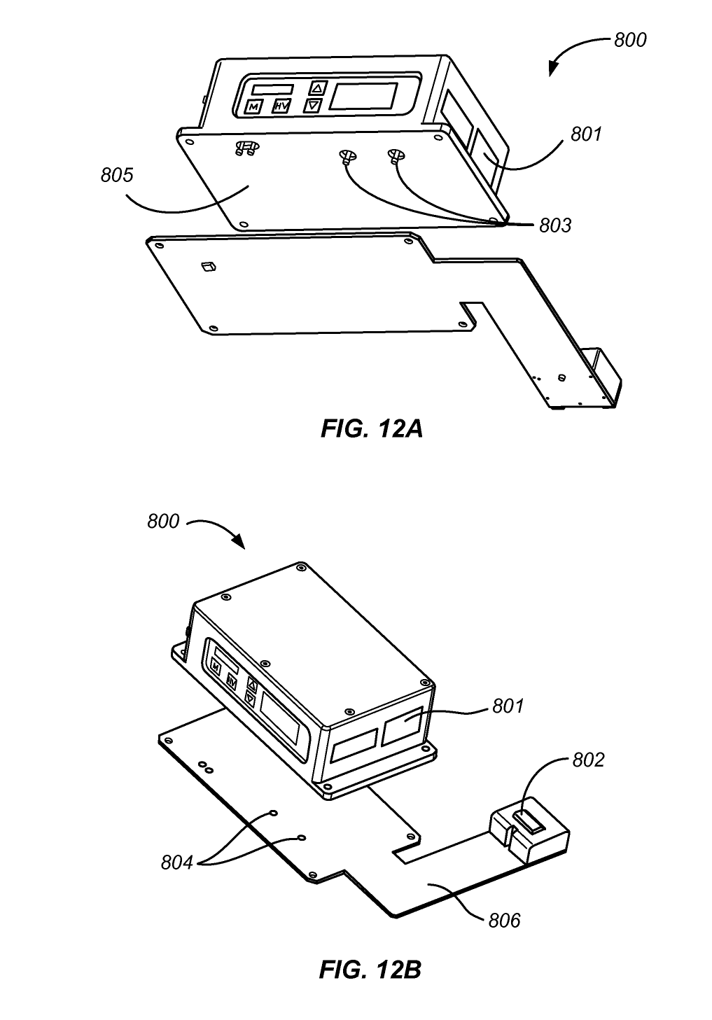

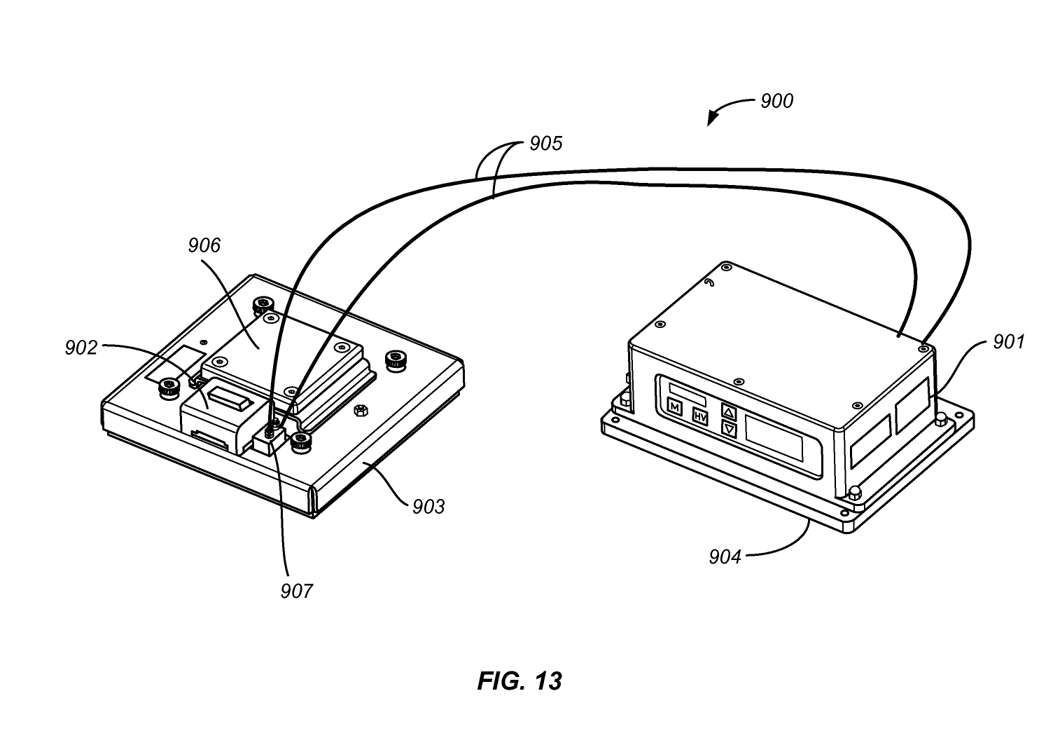

In some embodiments, the power supply 801 is separable from the frame, as illustrated in FIGS. 12A-12B. In some embodiments such as shown in configuration 900, the power supply 901 is remotely mounted off-board from the frame 903, in a docking station 904 as illustrated in FIG. 13.

In any one of the embodiments described herein, the power supply is configured to provide high voltage current. In any one of the embodiments described herein the power supply is configured to provide low voltage current. In any one of the embodiments described herein the power supply is configured to provide both high voltage and low voltage current.

In any one of the embodiments described herein, the power supply is configured to provide alternating current (AC) voltage. In any one of the embodiments described herein, the power supply is configured to provide direct current DC voltage.

As described herein, high voltage is defined as a range of DC voltage of any one or more of the following from 250 V to 8,000 V; from 500 V to 8,000 V; from 1,000 V to 8,000 V; from 1,500 V to 8,000 V; from 2,000 V to 8,000 V; from 3,000 V to 8,000 V; from 4,000 V to 8,000 V; from 5,000 V to 8,000 V; from 6,000 V to 8,000 V; from 7,000 V to 8,000 V; from 250 V to 1,000 V; from 250 V to 2,000 V; from 250 V to 4,000 V; from 500 V to 1,000 V; from 500 V to 2,000 V; from 500 V to 4,000 V; from 1,000 V to 2,000 V; from 1,000 V to 4,000 V; from 1,000 V to 6,000 V; from 2,000 V to 4,000 V; from 2,000 V to 6,000 V; from 4,000 V to 6,000 V; from 4,000 V to 8,000 V; and from 6,000 V to 8,000 V.

As described herein, high voltage is defined as a range of AC voltage of any one or more of the following from 250 Vᵣₘₛ to 8,000 Vᵣₘₛ; from 500 Vᵣₘₛ to 8,000 Vᵣₘₛ; from 1,000 Vᵣₘₛ to 8,000 Vᵣₘₛ; from 1,500 Vᵣₘₛ to 8,000 Vᵣₘₛ; from 2,000 Vᵣₘₛ to 8,000 Vᵣₘₛ; from 3,000 Vᵣₘₛ to 8,000 Vᵣₘₛ; from 4,000 Vᵣₘₛ to 8,000 Vᵣₘₛ; from 5,000 Vᵣₘₛ to 8,000 Vᵣₘₛ; from 6,000 Vᵣₘₛ to 8,000 Vᵣₘₛ; from 7,000 Vᵣₘₛ to 8,000 Vᵣₘₛ; from 250 Vᵣₘₛ to 1,000 Vᵣₘₛ; from 250 Vᵣₘₛ to 2,000 Vᵣₘₛ; from 250 Vᵣₘₛ to 4,000 Vᵣₘₛ; from 500 Vᵣₘₛ to 1,000 Vᵣₘₛ; from 500 Vᵣₘₛ to 2,000 Vᵣₘₛ; from 500 Vᵣₘₛ to 4,000 Vᵣₘₛ; from 1,000 Vᵣₘₛ to 2,000 Vᵣₘₛ; from 1,000 Vᵣₘₛ to 4,000 Vᵣₘₛ; from 1,000 Vᵣₘₛ to 6,000 Vᵣₘₛ; from 2,000 Vᵣₘₛ to 4,000 Vᵣₘₛ; from 2,000 Vᵣₘₛ to 6,000 Vᵣₘₛ; from 4,000 Vᵣₘₛ to 6,000 Vᵣₘₛ; from 4,000 Vᵣₘₛ to 8,000 Vᵣₘₛ; and from 6,000 Vᵣₘₛ to 8,000 Vᵣₘₛ.

As described herein, high voltage is defined as a range of DC voltage of any one or more of the following from about 250 V to about 8,000 V; from about 500 V to about 8,000 V; from about 1,000 V to about 8,000 V; from about 1,500 V to about 8,000 V; from about 2,000 V to about 8,000 V; from about 3,000 V to about 8,000 V; from about 4,000 V to about 8,000 V; from about 5,000 V to about 8,000 V; from about 6,000 V to about 8,000 V; from about 7,000 V to about 8,000 V; from about 250 V to about 1,000 V; from about 250 V to about 2,000 V; from about 250 V to about 4,000 V; from about 500 V to about 1,000 V; from about 500 V to about 2,000 V; from about 500 V to about 4,000 V; from about 1,000 V to about 2,000 V; from about 1,000 V to about 4,000 V; from about 1,000 V to about 6,000 V; from about 2,000 V to about 4,000 V; from about 2,000 V to about 6,000 V; from about 4,000 V to about 6,000 V; from about 4,000 V to about 8,000 V; and from about 6,000 V to about 8,000 V.

As described herein, high voltage is defined as a range of AC voltage of any one or more of the following from about 250 Vᵣₘₛ to about 8,000 Vᵣₘₛ; from about 500 Vᵣₘₛ to about 8,000 Vᵣₘₛ; from about 1,000 Vᵣₘₛ to about 8,000 Vᵣₘₛ; from about 1,500 Vᵣₘₛ to about 8,000 Vᵣₘₛ; from about 2,000 Vᵣₘₛ to about 8,000 Vᵣₘₛ; from about 3,000 Vᵣₘₛ to about 8,000 Vᵣₘₛ; from about 4,000 Vᵣₘₛ to about 8,000 Vᵣₘₛ; from about 5,000 Vᵣₘₛ to about 8,000 Vᵣₘₛ; from about 6,000 Vᵣₘₛ to about 8,000 Vᵣₘₛ; from about 7,000 Vᵣₘₛ to about 8,000 Vᵣₘₛ; from about 250 Vᵣₘₛ to about 1,000 Vᵣₘₛ; from about 250 Vᵣₘₛ to about 2,000 Vᵣₘₛ; from about 250 Vᵣₘₛ to about 4,000 Vᵣₘₛ; from about 500 Vᵣₘₛ to about 1,000 Vᵣₘₛ; from about 500 Vᵣₘₛ to about 2,000 Vᵣₘₛ; from about 500 Vᵣₘₛ to about 4,000 Vᵣₘₛ; from about 1,000 Vᵣₘₛ to about 2,000 Vᵣₘₛ; from about 1,000 Vᵣₘₛ to about 4,000 Vᵣₘₛ; from about 1,000 Vᵣₘₛ to about 6,000 Vᵣₘₛ; from about 2,000 Vᵣₘₛ to about 4,000 Vᵣₘₛ; from about 2,000 Vᵣₘₛ to about 6,000 Vᵣₘₛ; from about 4,000 Vᵣₘₛ to about 6,000 Vᵣₘₛ; from about 4,000 Vᵣₘₛ to about 8,000 Vᵣₘₛ; and from about 6,000 Vᵣₘₛ to about 8,000 Vᵣₘₛ.

As described herein, low voltage is defined as a range of DC voltage of any one or more of the following from 2.0 V to 249.99 V; from 2.0 V to 150.0 V; from 2.0 V to 100.0 V; from 2.0 V to 50.0 V; from 5.0 V to 249.99 V; from 5.0 V to 150.0 V; from 5.0 V to 100.0 V; from 5.0 V to 50.0 V; from 50.0 V to 150.0 V; from 100.0 V to 249.99 V; from 100.0 V to 130.0 V; and from 10.0 V and 30.0 V.

As described herein, low voltage is defined as a range of AC voltage of any one or more of the following from 2.0 Vᵣₘₛ to 249.99 Vᵣₘₛ; from 2.0 Vᵣₘₛ to 150.0 Vᵣₘₛ; from 2.0 Vᵣₘₛ to 100.0 Vᵣₘₛ; from 2.0 V to 50.0 Vᵣₘₛ; from 5.0 Vᵣₘₛ to 249.99 Vᵣₘₛ; from 5.0 Vᵣₘₛ to 150.0 Vᵣₘₛ; from 5.0 Vᵣₘₛ to 100.0 Vᵣₘₛ; from 5.0 Vᵣₘₛ to 50.0 Vᵣₘₛ; from 50.0 Vᵣₘₛ to 150.0 Vᵣₘₛ; from 100.0 Vᵣₘₛ to 249.99 Vᵣₘₛ; from 100.0 Vᵣₘₛ to 130.0 Vᵣₘₛ; and from 10.0 Vᵣₘₛ and 30.0 Vᵣₘₛ.

As described herein, low voltage is defined as a range of DC voltage of any one or more of the following from about 2.0 V to about 249.99 V; from about 2.0 V to about 150.0 V; from about 2.0 V to about 100.0 V; from about 2.0 V to about 50.0 V; from about 5.0 V to about 249.99 V; from about 5.0 V to about 150.0 V; from about 5.0 V to about 100.0 V; from about 5.0 V to about 50.0 V; from about 50.0 V to about 150.0 V; from about 100.0 V to about 249.99 V; from about 100.0 V to about 130.0 V; and from about 10.0 V and 30.0 V.

As described herein, low voltage is defined as a range of AC voltage of any one or more of the following from about 2.0 Vᵣₘₛ to about 249.99 Vᵣₘₛ; from about 2.0 Vᵣₘₛ to about 150.0 Vᵣₘₛ; from about 2.0 Vᵣₘₛ to about 100.0 Vᵣₘₛ; from about 2.0 V to about 50.0 Vᵣₘₛ; from about 5.0 Vᵣₘₛ to about 249.99 Vᵣₘₛ; from about 5.0 Vᵣₘₛ to about 150.0 Vᵣₘₛ; from about 5.0 Vᵣₘₛ to about 100.0 Vᵣₘₛ; from about 5.0 Vᵣₘₛ to about 50.0 Vᵣₘₛ; from about 50.0 Vᵣₘₛ to about 150.0 Vᵣₘₛ; from about 100.0 Vᵣₘₛ to about 249.99 Vᵣₘₛ; from about 100.0 Vᵣₘₛ to about 130.0 Vᵣₘₛ; and from about 10.0 Vᵣₘₛ and 30.0 Vᵣₘₛ.

The term “about” when used with respect to AC or DC voltage means variations of any of: up to 5%, up to 10%, up to 15%, up to 20%, up to 25%, and up to 30%. For example, if the amount of voltage is “about 120 V or 120 Vᵣₘₛ,” this may include variations of up to 5%, i.e.: 114 V to 126 V or 114 Vᵣₘₛ to 126 Vᵣₘₛ; variations of up to 10%, i.e.: 108 V to 132V or 108 Vᵣₘₛ to 132 Vᵣₘₛ, variations of up to 15%, i.e.: 102 V to 138 V or 102 Vᵣₘₛ to 138 Vᵣₘₛ; variations of up to 20%, i.e.: 96 V to 144 V or 96 Vᵣₘₛ to 144 Vᵣₘₛ; variations of up to 25%, i.e.: 90 V to 150 V or 90 Vᵣₘₛ to 150 Vᵣₘₛ; or variations of up to 30%, i.e.: 84 V to 156 V or 84 Vᵣₘₛ to 156 Vᵣₘₛ.

In any one of the embodiments described herein the power supply is configured to couple to the voltage connector 502, 602, 702, 802 and 902 with wire 905 utilizing commercially available wire connectors 907.

In some embodiments such as 900, the remotely mounted off-board power supply 901 is configured to reduce the overall weight or size of the frame 903 of the electroadhesive gripping system 900. In this embodiment the gripping mount 906 is mounted directly to the frame.

In some embodiments, the electroadhesive gripping system further comprises a electrically conductive film 806 dispersed between the power supply 501, 601, 701, 801, 901 and the superior surface of said frame 503, 603, 703, 903, and further interfaced with a voltage connector 502, 602, 702, 802 and configured to provide an electrical interface between the power supply and the electroadhesive film 607.

In some embodiments, the electrically conductive film 806 further comprises a printed circuit board configuration.

In any one of the embodiments described herein, the voltage connector, the wire, the wired connection, the printed circuit board and the electrically conductive film are configured to conduct high voltage current. In any one of the embodiments described herein, the voltage connector, the wire, the wired connection, the printed circuit board and the electrically conductive film are configured to conduct low voltage current. In any one of the embodiments described herein, the voltage connector, the wire, the wired connection, the printed circuit board and the electrically conductive film are configured to conduct both high voltage and low voltage current.

In any one of the embodiments described herein, the power supply is configured to provide alternating current (AC) voltage. In any one of the embodiments described herein, the power supply is configured to provide direct current DC voltage.

In some embodiments, as illustrated in configuration 800 the electrically conductive film 806 is separable from the power supply 601, 701, 801 and the superior surface of said frame as illustrated in FIGS. 12A-12B.

In some embodiments, the electrically conductive film 806 comprises two or more contact points 804 on the superior surface of the electrically conductive film 806 for receiving applied voltage from said power supply 801.

In any one of the embodiments just described, the power supply 501, 601, 701, 800, 901 further comprises two or more contact points 803 on the inferior surface 805 for applying said voltage to contact points 804 on the superior surface of said electrically conductive film 806.

Still further, in some embodiments, a contact point 803, 804 comprises: a pogo pin, a leaf spring, a carbon brush, a spring contact, a metallic contact button, a wiring connector, a wiring harness, a rare earth magnet, a ferrite magnet, an alnico magnet or a ferromagnetic contact.

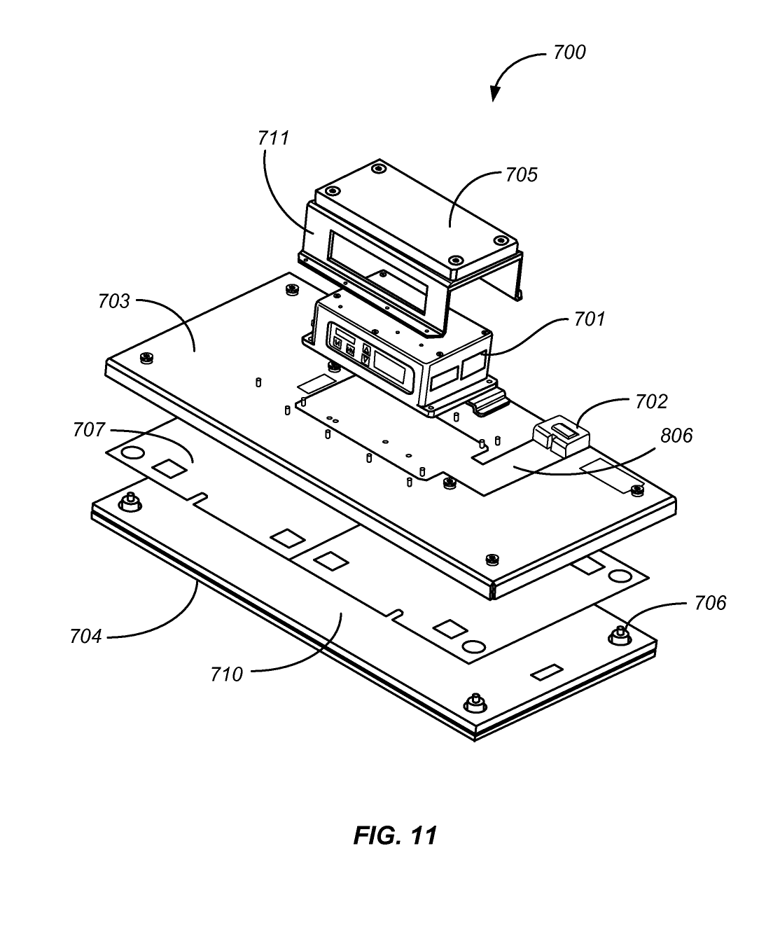

In any one of the embodiments described herein, the electroadhesive gripping system 700 further comprises a LED panel 707 as illustrated in FIG. 11. In some embodiments, the LED panel 707 is configured for placement between the frame 503, 603, 703 and the cartridge 504, 604, 704, or more specifically between the inferior surface of the frame and the superior surface 710 of the cartridge, as illustrated in FIG. 11.

In any of the embodiments described herein, a typical low DC voltage requirement for the LED panel is from 12.0 V to 24.0 V, or alternatively from about 12.0 V to about 24.0 V. In any of the embodiments described herein, a typical low AC voltage requirement for the LED panel is from 12.0 Vᵣₘₛ to 24.0 Vᵣₘₛ or alternatively from about 12.0 Vᵣₘₛ to about 24.0 Vᵣₘₛ.

The term “about” when used with respect to an amount of AC or DC voltage means variations of any of: up to 5%, up to 10%, up to 15%, up to 20%, up to 25%, and up to 30%. For example, if the amount of voltage is “about 120 V or 120 Vᵣₘₛ” this may include variations of up to 5%, i.e.: 114 to 126 V or 114 to 126 Vᵣₘₛ; variations of up to 10%, i.e.: 108 to 132V or 108 to 132 Vᵣₘₛ variations of up to 15%, i.e.: 102 to 138 V or 102 to 138 Vᵣₘₛ; variations of up to 20%, i.e.: 96 to 144 V or 96 to 144 Vᵣₘₛ; variations of up to 25%, i.e.: 90 to 150 V or 90 to 150 Vᵣₘₛ; or variations of up to 30%, i.e.: 84 to 156 V or 84 to 156 Vᵣₘₛ.

In some embodiments of the electroadhesive gripping system, the cartridge is configured with mounting protrusions 606, 706 comprising attachment means or features 611 for attaching the cartridge to the frame.

In some embodiments, the attachment features 611 comprise: threads, mechanical fasteners, bayonette connections, magnetic interfaces, quick disconnect features and detachable fastening mechanisms.

In some embodiments, the mounting protrusions 606, 706 are at least partially transparent. In some embodiments, the mounting protrusions 606, 706 are at least partially translucent.

As described herein, transparent is defined as allowing a range of available lumens capable of being produced by a local light source, from 75% to 100%; from 80% to 100%; from 85% to 100%; from 90% to 100%; and from 95% to 100%, to pass through the mounting protrusions. Alternatively, transparent is defined as allowing a range of available lumens capable of being produced by a local light source, from about 75% to about 100%; from about 80% to about 100%; from about 85% to about 100%; from about 90% to about 100%; and from about 95% to about 100%, As further described herein, translucent is defined as allowing a range of available lumens capable of being produced by a local light source, from 25% to 74.99%; from 30% to 74.99%; from 35% to 74.99%; from 40% to 74.99%; from 45% to 74.99%; from 50% to 74.99%; from 55% to 74.99%; from 60% to 74.99%; from 65% to 74.99%; and from 70% to 74.99% to pass through the mounting protrusions. Alternatively, translucent is defined as allowing a range of available lumens capable of being produced by a local light source, from about 25% to about 74.99%; from about 30% to about 74.99%; from about 35% to about 74.99%; from about 40% to about 74.99%; from about 45% to about 74.99%; from about 50% to about 74.99%; from about 55% to about 74.99%; from about 60% to about 74.99%; from about 65% to about 74.99%; and from about 70% to about 74.99% to pass through the mounting protrusions.

As used herein, “about” when used in reference to lumens means variation of 1%-5%, of 5%-10%, of 10%-20%, and/or of 10%-50% (as a percent of the percentage of the lumens, or as a variation of the percentage of the lumens). For example, if the lumens percentage is “about 20%”, the percentage may vary 5%-10% as a percent of the percentage i.e. from 19% to 21% or from 18% to 22%; alternatively the percentage may vary 5%-10% as an absolute variation of the percentage i.e. from 15% to 25% or from 10% to 30%.

A local light source can be provided by the LED panel, a camera, an internal or external lighting system or other optical system configured to interface with the electroadhesive gripping system.

In some embodiments of the electroadhesive gripping system, light from the LED panel 707 passes through the mounting protrusions 606, 706 to illuminate objects below the cartridge.

In some embodiments of the electroadhesive gripping system, the cartridge comprises a multi-layer construction, wherein the layers are either permanently or detachably bonded together with materials comprising: glue, epoxy, double-sided tape, magnetic attachment and mechanical attachment means, such as rivets, screws, bolts, sonic welding or woven threads.

In some embodiments, the cartridge layers and components comprise: electroadhesive film, polyethylene sheet, polyurethane foam, glass plate, shatter-proof glass, plastic plates, plastic films, and plastic sheets. Examples of such materials and plastics include, but are not limited to acrylic, Ultem, Plexiglas, Delrin or glass reinforced plastics among other plastic materials, metallic plates, including metallic shim plates, polyethylene terephthalate (PET) film, such as Mylar, double-stick tape, silicone, epoxies, spray adhesives and mechanical attachment features. Examples of mechanical attachment features 611 include but are not limited to plastic posts with threaded holes, screws, bolts, bayonette connections and similar quick disconnect devices.

In some embodiments of the electroadhesive gripping system, the cartridge layers and components consist of: electroadhesive film, polyethylene foam, glass plate, shatterproof glass, acrylic, polyethylene terephthalate (PET) film such as Mylar, polyurethane sheet, epoxies, double stick tapes; and mechanical attachment features. Examples of mechanical attachment features 611 include but are not limited to plastic posts with threaded holes, screws, bolts, bayonette connections and similar quick disconnect devices.

In some embodiments of the electroadhesive gripping system, the electrically conductive film is electrically insulated from said frame.

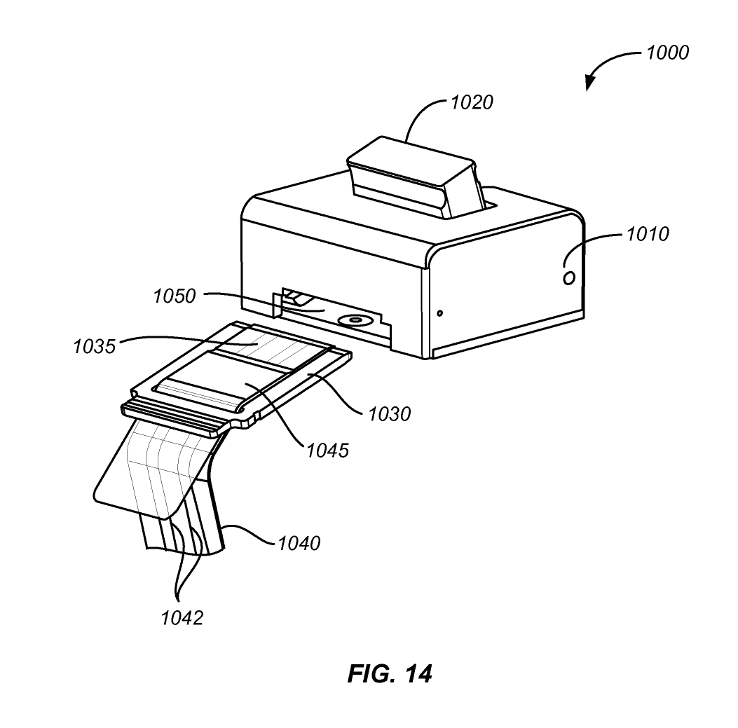

As illustrated in FIG. 14, embodiment 1000 of the electroadhesive gripping system, the electrically conductive film 1040 further comprises a printed circuit board.

In some embodiments, the printed circuit board 1035 is alternatively located in the voltage connector interface 1045.

In still other embodiments, the printed circuit board 1050 comprises a mounted voltage connector 1010 configured to detachably interface with the electroadhesive film voltage connector interface 1045.

In some embodiments of the electroadhesive gripping system, the voltage connector interface further 1045 comprises a reinforcing card 1030, configured to receive the end of the electroadhesive film 1040 comprising electrical traces 1042 from the one or more electrodes 609 contained in the electroadhesive film 607.

In some embodiments, the reinforcing card 1030 is further configured to accurately align the electrical traces 1042 of the of the electroadhesive film 1040 with mating contacts (not shown) on the printed circuit board 1035, 1050 of the voltage connector.

In some embodiments, the reinforcing card 1030 is further configured to provide a first component of a securing mechanism to removably secure the connection between the electroadhesive film voltage connector interface 1045 and the voltage connector 1010.

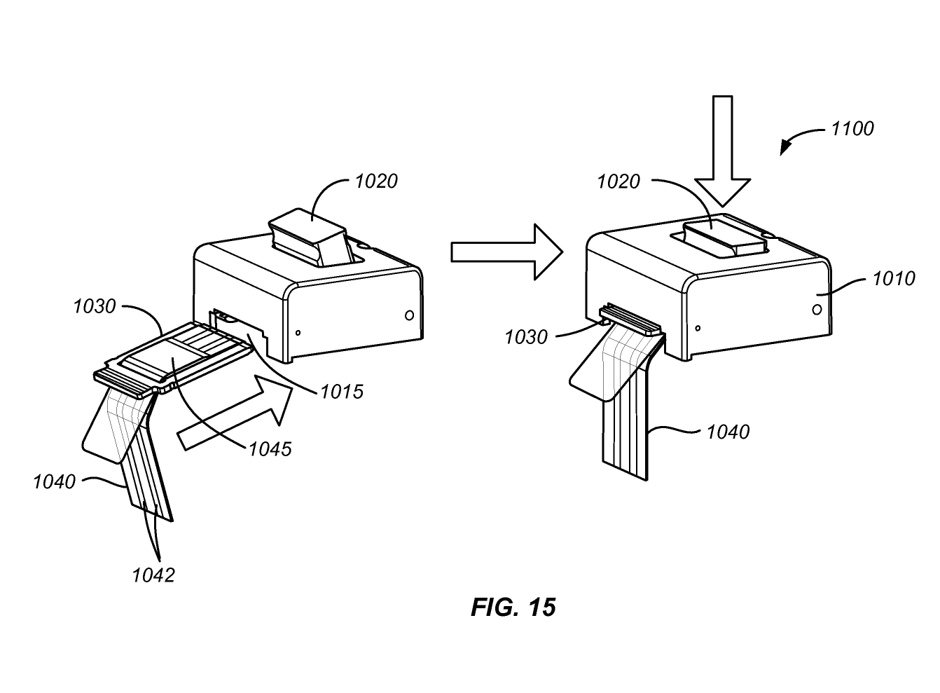

In some embodiments of the electroadhesive gripping system, the voltage connector 1010 comprises a second component 1020 of a securing mechanism to removably secure the connection between the electroadhesive film voltage connector interface and the voltage connector. As further illustrated in non-limiting examples 1000 and 1100 shown in FIGS. 14 and 15, the second component 1020 of a securing mechanism, a spring-loaded compressible latching device, is depressed onto the electroadhesive film voltage connector interface 1045 comprising the electrically conductive film 1040 and the reinforcing card 1030 after it is inserted into the voltage connector opening 1015, thus engaging a releasable capturing mechanism within the voltage connector 1010. Actively depressing the latch 1020 a second time would release the capturing mechanism.

In some embodiments, the voltage connector further comprises a compressible gasket (not shown) to prevent electrical arcing when the electroadhesive film voltage connector interface 1045 is secured in the voltage connector 1010.

In some embodiments, the compressible gasket comprises: paper reinforced phenolics, fluorinated ethylene propylene (FEP), neoprene, nylon, polyethylene terephthalate (PET or PETG), polyester such as Mylar, polystyrene, polysulfone, polyurethane, silicon rubber, vinyl and foam variations thereof.

In some embodiments, the voltage connector further comprises an insulating layer between the contact points of the electrical traces 1042 on the electroadhesive film 1040 to prevent electrical arcing between the electrical traces when the electroadhesive film voltage connector interface is secured in the voltage connector.

In some embodiments of the electroadhesive gripping system, the voltage connector 1010 interface further comprises an insulating layer between electrical traces from the one or more electrodes on the electroadhesive film to prevent electrical arcing between the electrical traces when the electroadhesive film voltage connector interface is secured in the voltage connector.

In some embodiments of the system, the insulting layer comprises: acrylonitrile, butadiene, and styrene (A.B.S.), acetate, acrylic, ceramics, glass ceramics, woven glass laminates, Delrin, epoxy/fiberglass laminate, fiberglass laminate, fluorinated ethylene propylene (FEP), high-impact polystyrene (HIPS), polyimide, polyimide film, unfilled polyimide, aromatic polyamide, polyvinylidene difluoride (PVDF), mica, neoprene, nylon, PerFluoroAlkoxy (PFA), polyphenylene oxide and styrene blends (PPO), PolyEtherEther-Ketone (PEEK), polyethylene terephthalate (PET or PETG), polyester (Mylar), phenolics, polycarbonates, polystyrene, polyolefins, polysulfone, polyurethane, polytetrafluoroethylene (PTFE), polyvinylchloride (PVC), polystyrene, polyphenylene sulfide (PPS), silicon rubber, silicon/fiberglass, polyphenylene sulfide (PPS), polyetherimide (PEI), vinyl, electrical insulating papers and electrical insulating tapes, or a combination thereof.

As used herein, and unless otherwise specified, the term “about” or “approximately” means an acceptable error for a particular value as determined by one of ordinary skill in the art, which depends in part on how the value is measured or determined. In certain embodiments, the term “about” or “approximately” means within 1, 2, 3, or 4 standard deviations. In certain embodiments, the term “about” or “approximately” means within 30%, 25%, 20%, 15%, 10%, 9%, 8%, 7%, 6%, 5%, 4%, 3%, 2%, 1%, 0.5%, 0.1%, or 0.05% of a given value or range.

While preferred embodiments of the present invention have been shown and described herein, it will be obvious to those skilled in the art that such embodiments are provided by way of example only. Numerous variations, changes, and substitutions will now occur to those skilled in the art without departing from the invention. It should be understood that various alternatives to the embodiments of the invention described herein may be employed in practicing the invention. It is intended that the following claims define the scope of the invention and that methods and structures within the scope of these claims and their equivalents be covered thereby.

What is claimed is:

1. An electroadhesive gripping system comprising:
a frame having a superior surface and an inferior surface;
a cartridge having a superior surface and inferior surface, wherein said superior surface is detachably connectable to said inferior surface of said frame;
an electroadhesive film with one or more electrodes at or near a gripping surface, a backing surface at least partially covering and connectable to the inferior surface of said cartridge and comprising a voltage connector interface comprising electrical traces from the electrodes; and
a power supply configured to apply voltage to the one or more electrodes of the electroadhesive film.

2. The electroadhesive gripping system of claim 1, further comprising a voltage connector coupled to said frame configured to provide an electrical connection receptacle between the power supply and the detachably connectable electroadhesive film voltage connector interface.

3. The electroadhesive gripping system of claim 1, wherein the power supply is separable from the frame.

4. The electroadhesive gripping system of claim 3, wherein the power supply is remotely mounted off-board from the frame in a docking station.

5. The electroadhesive gripping system of claim 4, wherein the power supply is configured to couple to the voltage connector with a wire and a wired connection.

6. The electroadhesive gripping system of claim 4, wherein the remotely mounted off-board power supply is configured to reduce the overall weight or size of the frame of the electroadhesive gripping system.

7. The electroadhesive gripping system of claim 1, further comprising an electrically conductive film dispersed between the power supply and the superior surface of said frame, interfaced with a voltage connector, and configured to provide an electrical interface between the power supply and the electroadhesive film.

8. The electroadhesive gripping system of claim 7, wherein the electrically conductive film further comprises a printed circuit board configuration.

9. The electroadhesive gripping system of claim 7, wherein the electrically conductive film is separable from the power supply and the superior surface of said frame.

10. The electroadhesive gripping system of claim 7, wherein the electrically conductive film comprises two or more contact points for one or more of receiving applied voltage from said power supply or applying said voltage to said electrically conductive film.

11. (canceled)

12. The electroadhesive gripping system of claim 10, wherein a contact point comprises:
a pogo pin;
a leaf spring;
a carbon brush;
a spring contact;
a metallic contact button;
a wiring connector;
a wiring harness;
a rare earth magnet;
a ferrite magnet;
an alnico magnet; or
a ferromagnetic contact.

13. The electroadhesive gripping system of claim 1, further comprising a LED panel.

14. The electroadhesive gripping system of claim 13, wherein the LED panel is configured for placement between the frame and the cartridge.

15. The electroadhesive gripping system of claim 1, wherein the cartridge is configured with mounting protrusions comprising attachment features for attaching the cartridge to the frame.

16. The electroadhesive gripping system of claim 15, wherein said attachment features comprise:
threads;
mechanical fasteners;
bayonette connections;
magnetic interfaces
quick disconnect features; and
detachable fastening mechanisms.

17. The electroadhesive gripping system of claim 15, wherein said mounting protrusions are one or more of at least partially transparent or at least partially translucent.

18. (canceled)

19. The electroadhesive gripping system of claim 17 wherein light from the LED panel passes through the mounting protrusions to illuminate objects below the cartridge.

20. The electroadhesive gripping system of claim 1, wherein the cartridge comprises a multi-layer construction, wherein the layers are either permanently or detachably bonded together with materials comprising:
glue;
epoxy;
double-sided tape;
magnetic attachment; and
mechanical attachment means.

21. The electroadhesive gripping system of claim 1, wherein the cartridge layers and components comprise:
electroadhesive film;
polyethylene sheet;
polyurethane foam;
glass plate;
shatter-proof glass;
plastic plates;
plastic films;
plastic sheets;
metallic plates;
polyethylene terephthalate film;
double-stick tape;
silicone;
epoxies;
spray adhesives; and
mechanical attachment features.

22. The electroadhesive gripping system of claim 1, wherein the cartridge layers and components consist of:
electroadhesive film;
polyethylene foam;
glass plate;
shatterproof glass;
acrylic;
polyethylene terephthalate (PET) film;
polyurethane sheet;
epoxies;
double stick tapes; and
mechanical attachment features.

23. The electroadhesive gripping system of claim 7, wherein the electrically conductive film is electrically insulated from said frame.

24. The electroadhesive gripping system of claim 7, wherein the electrically conductive film further comprises a printed circuit board.

25. The electroadhesive gripping system of claim 24, wherein the printed circuit board comprising a mounted voltage connector is configured to detachably interface with the electroadhesive film voltage connector interface.

26. The electroadhesive gripping system of claim 25, wherein the voltage connector interface further comprises a reinforcing card, configured to receive the end of the electroadhesive film comprising the electrical traces from the one or more electrodes contained in the electroadhesive film.

27. The electroadhesive gripping system of claim 26, wherein the reinforcing card is further configured to accurately align the electrical traces of the of the electroadhesive film with mating contacts on the printed circuit board of the voltage connector.

28. The electroadhesive gripping system of claim 26, wherein the reinforcing card is further configured to provide a first component of a securing mechanism to removably secure the connection between the electroadhesive film voltage connector interface and the voltage connector.

29. The electroadhesive gripping system of claim 26, wherein the voltage connector comprises a second component of a securing mechanism to removably secure the connection between the electroadhesive film voltage connector interface and the voltage connector.

30. The electroadhesive gripping system of claim 26, wherein the voltage connector further comprises a compressible gasket to prevent electrical arcing when the electroadhesive film voltage connector interface is secured in the voltage connector.

31. The electroadhesive gripping system of claim 25, wherein the voltage connector further comprises an insulating layer between the electrical traces on the electroadhesive film to prevent electrical arcing between the electrical traces when the electroadhesive film voltage connector interface is secured in the voltage connector.

32. The electroadhesive gripping system of claim 1, wherein the voltage connector interface further comprises an insulating layer between the contact points of the electrical traces from the one or more electrodes on the electroadhesive film to prevent electrical arcing between the electrical traces when the electroadhesive film voltage connector interface is secured in the voltage connector.

33. The electroadhesive gripping system of claim 32, wherein the insulting layer comprises:
acrylonitrile, butadiene, and styrene blends;
acetate;
acrylic;
ceramics;
glass ceramics;
woven glass laminates;
Delrin;
epoxy/fiberglass laminate;
fiberglass laminate;
fluorinated ethylene propylene;
high-impact polystyrene;
polyimide;
polyimide film;
unfilled polyimide;
aromatic polyamide;
polyvinylidene difluoride;
mica;
neoprene;
nylon;
PerFluoroAlkoxy;
polyphenylene oxide and styrene blends;
PolyEtherEther-Ketone;
polyethylene terephthalate;
polyester;
phenolics;
polycarbonates;
polystyrene;
polyolefins;
polysulfone;
polyurethane;
polytetrafluoroethylene;
polyvinylchloride;
polystyrene;
polyphenylene sulfide;
silicon rubber;
silicon/fiberglass;
polyphenylene sulfide;
polyetherimide;
vinyl;
electrical insulating papers; and
electrical insulating tapes.

34. The electroadhesive gripping system of claim 30, wherein the compressible gasket comprises:
paper reinforced phenolics;
fluorinated ethylene propylene;
neoprene;
nylon;
polyethylene terephthalate;
polyester;
polystyrene;
polysulfone;
polyurethane;
silicon rubber;
vinyl, and
foam variations thereof.

35. The electroadhesive gripping system of claim 1, wherein the power supply is configured to provide high voltage current.

36. The electroadhesive gripping system of claim 1, wherein the power supply is configured to provide low voltage current.

37. The electroadhesive gripping system of claim 1, wherein the power supply is configured to provide both high voltage and low voltage current.

38. The electroadhesive gripping system of claim 2, wherein the voltage connector configured to one or more of conduct high voltage current or conduct low voltage current.

39. The electroadhesive gripping system of claim 5 wherein the wire and the wired connection are configured to conduct low voltage current.

40. The electroadhesive gripping system of claim 7 wherein the electrically conductive film is configured to one or more of conduct high voltage current or conduct low voltage current.

41. The electroadhesive gripping system of claim 13, wherein the LED panel is configured to operate on low voltage current.

42. The electroadhesive gripping system of claim 1, wherein the electrical traces are configured to deliver high voltage current.

43. The electroadhesive gripping system of claim 1, wherein the electrical traces are configured to deliver low voltage current.

44. The electroadhesive gripping system of claim 1, wherein the electrical traces are configured to deliver both high voltage and low voltage current.
